(19) United States
(12) Patent Application Publication
(10) Pub. No.: US 2025/0374619 A1
(43) Pub. Date: Dec. 4, 2025

(54) GATED SUBFIN REDUCTION TECHNIQUES IN NANORIBBON-BASED TRANSISTORS

(71) Applicant: Intel Corporation, Santa Clara, CA (US)

(72) Inventors: Shao Ming Koh, Tigard, OR (US); Jeanne Luce, Hillsboro, OR (US); Brandon Kilduff, Hillsboro, OR (US); Ryan Pearce, Beaverton, OR (US); Sudipto Naskar, Portland, OR (US); Joon Goo Hong, Austin, TX (US); Nick Lindert, Portland, OR (US); Steven Jaloviar, Banks, OR (US); Harry Gomez, Hillsboro, OR (US)

(21) Appl. No.: 18/732,978

(22) Filed: Jun. 4, 2024

(51) Int. Cl. H01L 29/06; H01L 21/822; H01L 27/06; H01L 27/092; H01L 29/423; H01L 29/778; H01L 29/786

(52) U.S. Cl. CPC H10D 62/118; H10D 30/47; H10D 30/6735; H10D 30/6757; H10D 84/038; H10D 84/856; H10D 88/00; H10D 88/01

(57) ABSTRACT

Disclosed herein are integrated circuit (IC) structures fabricated with techniques to reduce a gated subfin region in nanoribbon-based transistors. In one example, the technique involves depositing a film over the shallow trench insulator (STI) between adjacent subfins, where the film has a different material composition than the STI. In accordance with examples described herein, the film over the STI can protect the STI during various etch and clean processes to minimize unintentional recession of the STI and thus minimize the presence of gated subfins in the final IC structure. In some examples, the film may be present over the STI in the final IC structure in a plane with source or drain contact structures, and may also be present over the STI in a metal gate region.

### BACKGROUND

For the past several decades, the scaling of features in integrated circuits (ICs) has been a driving force behind an ever-growing semiconductor industry. Scaling to smaller and smaller features enables increased densities of functional units on the limited real estate of semiconductor chips. For example, shrinking transistor size allows for the incorporation of an increased number of memory or logic devices on a chip, lending to the fabrication of products with increased capacity. The drive for the ever-increasing capacity, however, is not without issue. The necessity to optimize fabrication and performance of each component is becoming increasingly significant.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 provides a perspective view of an example nanoribbon-based field-effect transistor (FET), according to some embodiments of the present disclosure.

FIG. 2 is a top-down view of an IC device fabricated using techniques to reduce a gated subfin in a nanoribbon-based transistor, according to one embodiment of the present disclosure.

FIGS. 3A-3C, 4, and 5A-5B are cross-sectional views of IC structures fabricated using techniques to reduce a gated subfin in a nanoribbon-based transistor, according to one embodiment of the present disclosure.

FIG. 6 is a flow diagram of an example method for fabricating an IC structure using techniques to reduce a gated subfin in a nanoribbon-based transistor, in accordance with some embodiments.

FIGS. 7A-7H provide cross-sectional side views at various stages in the fabrication of an example IC structure according to the method of FIG. 6, in accordance with some embodiments.

FIG. 8 is a top view of a wafer and dies that may include any of the IC devices disclosed herein, in accordance with any of the embodiments disclosed herein.

FIG. 9 is a side, cross-sectional view of an IC package that may include any of the IC devices disclosed herein, in accordance with various embodiments.

FIG. 10 is a side, cross-sectional view of an IC device assembly that may include any of the IC devices disclosed herein, in accordance with any of the embodiments disclosed herein.

FIG. 11 is a block diagram of an example electrical device that may include any of the IC devices disclosed herein, in accordance with any of the embodiments disclosed herein.

### DETAILED DESCRIPTION

Disclosed herein are integrated circuit (IC) structures and devices fabricated with techniques to reduce a gated subfin in a nanoribbon-based transistor. The systems, methods and devices of this disclosure each have several innovative aspects, no single one of which is solely responsible for all desirable attributes disclosed herein. Details of one or more implementations of the subject matter described in this specification are set forth in the description below and the accompanying drawings.

Non-planar transistors such as double-gate transistors, tri-gate transistors, FinFETs, and nanowire/nanoribbon/nanosheet transistors refer to transistors having a non-planar architecture. In comparison to a planar architecture where the transistor channel has only one confinement surface, a non-planar architecture is any type of architecture where the transistor channel has more than one confinement surface. A confinement surface refers to a particular orientation of the channel surface that is confined by the gate field. Non-planar transistors potentially improve performance relative to transistors having a planar architecture, such as single-gate transistors.

Nanoribbon-based transistors may be particularly advantageous for continued scaling of complementary metal-oxide-semiconductor (CMOS) technology nodes due to the potential to form gates on all four sides of a channel material (hence, such transistors are sometimes referred to as “gate all around” transistors). As used herein, the term “nanoribbon” refers to an elongated structure of a semiconductor material having a longitudinal axis parallel to a support structure (e.g., a substrate, a die, a chip, or a wafer) over which such a structure is built. Typically, a length of a such a structure (i.e., a dimension measured along the longitudinal axis, shown in the present drawings to be along the y-axis of an example x-y-z coordinate system) is greater than each of a width (i.e., a dimension measured along the x-axis of the example coordinate system shown in the present drawings) and a thickness/height (i.e., a dimension measured along the z-axis of the example coordinate system shown in the present drawings). In some settings, the terms “nanoribbon” or “nanosheet” have been used to describe elongated semiconductor structures that have a rectangular transverse cross-section (i.e., a cross-section in a plane perpendicular to the longitudinal axis of the structure), while the term “nanowire” has been used to describe similar elongated structures but with circular transverse cross-sections. In the present disclosure, the term “nanoribbon” is used to refer to all such nanowires, nanoribbons, and nanosheets, as well as elongated semiconductor structures with a longitudinal axis parallel to the support structures and with having transverse cross-sections of any geometry (e.g., transverse cross-sections in the shape of an oval or a polygon with rounded corners). A transistor may then be described as a “nanoribbon-based transistor” if the channel of the transistor is a portion of a nanoribbon, i.e., a portion around which a gate stack of a transistor may wrap around. The semiconductor material in the portion of the nanoribbon that forms a channel of a transistor may be referred to as a “channel material,” with source and drain (S/D) regions of a transistor provided on either side of the channel material.

Typically, nanoribbon-based transistor arrangements include stacks of nanoribbons, where each stack includes two or more nanoribbons stacked above one another, with a single gate stack that includes a work function material provided for an entire stack or multiple stacks. Optionally, the gate stack may also include a gate dielectric material around each nanoribbon. Such nanoribbon-based transistor arrangements may be fabricated by, first, providing a stack of alternating layers of first and second semiconductor materials over a support (e.g., a substrate, a die, a wafer, or a chip). The first semiconductor material is a material that will later form nanoribbons, while the second semiconductor material is a material that is etch-selective with respect to the first semiconductor material so that it may later be removed to separate different nanoribbons of a stack from one another. For example, the first semiconductor material may be silicon, while the second semiconductor material may be silicon germanium. In such a fabrication process, the first semiconductor material provides the bottom layer of the stack as well as two or more layers above the bottom layer, alternating with layers of the second semiconductor material. The fabrication process further includes patterning the stack of alternating layers, as well as, possibly, an upper portion of the support into a fin to define the width of future nanoribbons. Sidewalls of a bottom portion of the fin are enclosed by an insulator material commonly referred to as a “shallow trench insulator” (STI) and such a bottom portion of the fin enclosed by the STI is commonly referred to as a “subfin,” similar to a subfin portion of fin-based transistors. The subfin may include the bottom layer of the first semiconductor material of the stack and an upper portion of the support over which the stack was provided. The fabrication process further includes removing the second semiconductor material from the fin to release nanoribbons formed by the fin portions of the first semiconductor material above the subfin. After the nanoribbons are released, a gate stack is provided around portions of the nanoribbons.

As a result of one or more etch and clean processes, the STI may become unintentionally recessed. In cases where the recession of the STI is significant, deposition of the gate electrode material may result in metal wrapping around portions of the subfins in the areas where the STI is recessed. The portion of the subfin with metal wrapping around it may be referred to as a “gated subfin.” A gated subfin region may have high capacitance and negatively impact device performance. While in some examples a semiconductor portion of the subfin may be removed to reduce capacitance, the metal portion wrapping around the original subfin may remain, limiting the extent to which capacitance can be reduced.

In accordance with examples described herein, techniques to reduce the gated subfin in nanoribbon-based transistors involve depositing a film over the STI, where the film has a different material composition than the STI. For example, if the STI includes an oxide (e.g., silicon oxide), the film may include a nitride (e.g., silicon nitride, titanium nitride, or another nitride-based film). In one example, the method involves depositing a film on the STI as well as on sidewalls of the fins, performing a treatment on the portions of the film on the STI to make it more difficult to remove relative to the film on the sidewalls, and removing the film from the sidewalls without removing the film from over the STI. In other examples, the film may be selectively deposited on the STI. In accordance with examples described herein, the film over the STI can protect the STI during various etch and clean processes to minimize unintentional recession of the STI and thus minimize the presence of gated subfins in the final IC structure. In some examples, the film may be present over the STI in the final IC structure in a plane with the source or drain contact structures, and in some cases may also be present over the STI in the metal gate region.

In one example, an IC structure includes a first stack of nanoribbons and a second stack of nanoribbons over a substrate, a first region of a doped semiconductor material in the first stack of nanoribbons in a plane that is orthogonal to the substrate, and a second region of a doped semiconductor material in the second stack of nanoribbons in the plane. The IC structure includes a first subfin structure below and substantially aligned with the first stack of nanoribbons and a second subfin structure below and substantially aligned with the second stack of nanoribbons, and an insulator material (e.g., STI) between and coplanar with the first subfin structure and the second subfin structure. The IC structure includes a film (e.g., a nitride-based film or other film having a different material composition than the STI) over the insulator material in the plane.

IC structures as described herein, in particular IC structures fabricated with techniques to reduce a gated subfin in a nanoribbon-based transistor, may be implemented in one or more components associated with an IC or/and between various such components. In various embodiments, components associated with an IC include, for example, transistors, diodes, power sources, resistors, capacitors, inductors, sensors, transceivers, receivers, antennas, etc. Components associated with an IC may include those that are mounted on an IC or those connected to an IC. The IC may be either analog or digital and may be used in a number of applications, such as microprocessors, optoelectronics, logic blocks, audio amplifiers, etc., depending on the components associated with the IC. In some embodiments, IC structures as described herein may be included in a radio frequency IC (RFIC), which may, e.g., be included in any component associated with an IC of an RF receiver, an RF transmitter, or an RF transceiver, e.g., as used in telecommunications within base stations (BS) or user equipment (UE). Such components may include, but are not limited to, power amplifiers, low-noise amplifiers, RF filters (including arrays of RF filters, or RF filter banks), switches, upconverters, downconverters, and duplexers. In some embodiments, IC structures as described herein may be included in memory devices or circuits. In some embodiments, IC structures as described herein may be employed as part of a chipset for executing one or more related functions in a computer.

For purposes of explanation, specific numbers, materials, and configurations are set forth in order to provide a thorough understanding of the illustrative implementations. However, it will be apparent to one skilled in the art that the present disclosure may be practiced without the specific details or/and that the present disclosure may be practiced with only some of the described aspects. In other instances, well-known features are omitted or simplified in order not to obscure the illustrative implementations. The terms “substantially,” “close,” “approximately,” “near,” and “about,” generally refer to being within +/−10% of a target value, e.g., within +/−5% of a target value, based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−10% of a target value, e.g., within +/−5% of a target value, based on the context of a particular value as described herein or as known in the art.

In the following description, references are made to the accompanying drawings that form a part hereof, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense.

In the drawings, while some schematic illustrations of example structures of various devices and assemblies described herein may be shown with precise right angles and straight lines, this is simply for ease of illustration, and embodiments of these assemblies may be curved, rounded, or otherwise irregularly shaped as dictated by, and sometimes inevitable due to, the fabricating processes used to fabricate semiconductor device assemblies. Therefore, it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication. Inspection of layout and mask data and reverse engineering of parts of a device to reconstruct the circuit using e.g., optical microscopy, TEM, or SEM, and/or inspection of a cross-section of a device to detect the shape and the location of various device elements described herein using, e.g., Physical Failure Analysis (PFA) would allow determination of presence of IC structures fabricated with techniques to reduce a gated subfin in a nanoribbon-based transistor as described herein.

Various aspects of the illustrative implementations will be described using terms commonly employed by those skilled in the art to convey the substance of their work to others skilled in the art. For example, the terms “oxide,” “carbide,” “nitride,” “silicide,” etc. refer to compounds containing, respectively, oxygen, carbon, nitrogen, silicon, etc.; the term “high-k dielectric” refers to a material having a higher dielectric constant than silicon oxide; the term “low-k dielectric” refers to a material having a lower dielectric constant than silicon oxide. Materials referred to herein with formulas or as compounds cover all materials that include elements of the formula or a compound, e.g., TiSi or titanium silicide may refer to any material that includes titanium and silicon, WN or tungsten nitride may refer to any material that includes tungsten and nitrogen, etc. The term “insulating” means “electrically insulating,” the term “conducting” means “electrically conducting,” unless otherwise specified. Furthermore, the term “connected” may be used to describe a direct electrical or magnetic connection between the things that are connected, without any intermediary devices, while the term “coupled” may be used to describe either a direct electrical or magnetic connection between the things that are connected, or an indirect connection through one or more passive or active intermediary devices. A first component described to be electrically coupled to a second component means that the first component is in conductive contact with the second component (i.e., that a conductive pathway is provided to route electrical signals/power between the first and second components).

Various operations may be described as multiple discrete actions or operations in turn, in a manner that is most helpful in understanding the claimed subject matter. However, the order of description should not be construed as to imply that these operations are necessarily order dependent. These operations may not be performed in the order of presentation. Operations described may be performed in a different order from the described embodiment. Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges.

The description uses the phrases “in an embodiment” or “in embodiments,” which may each refer to one or more of the same or different embodiments. The terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner. Although some materials may be described in singular form, such materials may include a plurality of materials, e.g., a semiconductor material may include two or more different semiconductor materials.

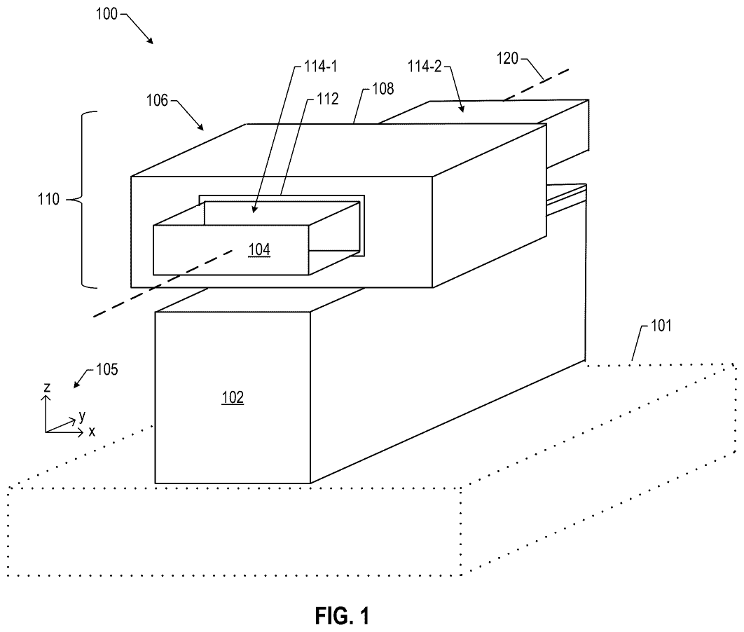

FIG. 1 provides a perspective view of an example IC structure 100 with a nanoribbon-based transistor 110 (in particular, a FET), according to some embodiments of the present disclosure. As shown in FIG. 1, the IC structure 100 includes a semiconductor material formed as a nanoribbon 104 extending substantially parallel to a support 101. The transistor 110 may be formed on the basis of the nanoribbon 104 by having a gate stack 106 wrap around at least a portion of the nanoribbon referred to as a “channel portion” and by having source and drain regions, shown in FIG. 1 as a first S/D region 114-1 and a second S/D region 114-2, on either side of the gate stack 106. One of the S/D regions 114 is a source region and the other one is a drain region. However, because, as is common in the field of FETs, designations of source and drain are often interchangeable, they are simply referred to herein as a first S/D region 114-1 and a second S/D region 114-2.

The nanoribbon 104 may take the form of a nanowire or nanoribbon, for example. In some embodiments, an area of a transversal cross-section of the nanoribbon 104 (i.e., an area in the x-z plane of the example coordinate system x-y-z shown in FIG. 1, perpendicular to a longitudinal axis 120 of the nanoribbon 104) may be between about 25 and 10000 square nanometers, including all values and ranges therein (e.g., between about 25 and 1000 square nanometers, or between about 25 and 500 square nanometers). In some embodiments, a width of the nanoribbon 104 (i.e., a dimension measured in a plane parallel to the support 101 and in a direction perpendicular to the longitudinal axis 120 of the nanoribbon 104, e.g., along the y-axis of the example coordinate system shown in FIG. 1) may be at least about 3 times larger than a height of the nanoribbon 104 (i.e., a dimension measured in a plane perpendicular to the support 101, e.g., along the z-axis of the example coordinate system shown in FIG. 1), including all values and ranges therein, e.g., at least about 4 times larger, or at least about 5 times larger. Although the nanoribbon 104 illustrated in FIG. 1 is shown as having a rectangular cross-section, the nanoribbon 104 may instead have a cross-section that is rounded at corners or otherwise irregularly shaped, and the gate stack 106 may conform to the shape of the nanoribbon 104. The term “face” of a nanoribbon may refer to the side of the nanoribbon 104 that is larger than the side perpendicular to it (when measured in a plane substantially perpendicular to the longitudinal axis 120 of the nanoribbon 104), the latter side being referred to as a “sidewall” of a nanoribbon.

In various embodiments, the semiconductor material of the nanoribbon 104 may be composed of semiconductor material systems including, for example, N-type or P-type materials systems. In some embodiments, the nanoribbon 104 may include a high mobility oxide semiconductor material, such as tin oxide, antimony oxide, indium oxide, indium tin oxide, titanium oxide, zinc oxide, indium zinc oxide, gallium oxide, titanium oxynitride, ruthenium oxide, or tungsten oxide. In some embodiments, the nanoribbon 104 may include a combination of semiconductor materials. In some embodiments, the nanoribbon 104 may include a monocrystalline semiconductor, such as silicon (Si) or germanium (Ge). In some embodiments, the nanoribbon 104 may include a compound semiconductor with a first sub-lattice of at least one element from group Ill of the periodic table (e.g., Al, Ga, In), and a second sub-lattice of at least one element of group V of the periodic table (e.g., P, As, Sb).

For some example N-type transistor embodiments (i.e., for the embodiments where the transistor 110 is an N-type metal-oxide-semiconductor (NMOS) transistor), the channel material of the nanoribbon 104 may include a Ill-V material having a relatively high electron mobility, such as, but not limited to InGaAs, InP, InSb, and InAs. For some such embodiments, the channel material of the nanoribbon 104 may be a ternary III-V alloy, such as InGaAs, GaAsSb, InAsP, or InPSb. For some InₓGa₁₋ₓAs fin embodiments, In content (x) may be between 0.6 and 0.9, and may advantageously be at least 0.7 (e.g., In_{0.7}Ga_{0.3}As). For some example P-type transistor embodiments (i.e., for the embodiments where the transistor 110 is a P-type metal-oxide-semiconductor (PMOS) transistor), the channel material of the nanoribbon 104 may advantageously be a group IV material having a high hole mobility, such as, but not limited to Ge or a Ge-rich SiGe alloy. For some example embodiments, the channel material of the nanoribbon 104 may have a Ge content between 0.6 and 0.9, and advantageously may be at least 0.7.

In some embodiments, the channel material of the nanoribbon 104 may be a thin-film material, such as a high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, or tungsten oxide. In general, if the transistor formed in the nanoribbon is a thin-film transistor (TFT), the channel material of the nanoribbon 104 may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, N- or P-type amorphous or polycrystalline silicon, germanium, indium gallium arsenide, silicon germanium, gallium nitride, aluminum gallium nitride, indium phosphite, and black phosphorus, each of which may possibly be doped with one or more of gallium, indium, aluminum, fluorine, boron, phosphorus, arsenic, nitrogen, tantalum, tungsten, and magnesium, etc. In some embodiments, the channel material of the nanoribbon 104 may have a thickness between about 5 and 75 nanometers, including all values and ranges therein. In some embodiments, a thin-film channel material may be deposited at relatively low temperatures, which allows depositing the channel material within the thermal budgets imposed on back end fabrication to avoid damaging other components, e.g., front end components such as the logic devices.

A gate stack 106 including a gate electrode material 108 and, optionally, a gate dielectric material 112, may wrap entirely or almost entirely around a portion of the nanoribbon 104 as shown in FIG. 1, with the active region (channel region) of the channel material of the transistor 110 corresponding to the portion of the nanoribbon 104 wrapped by the gate stack 106. As shown in FIG. 1, the gate dielectric material 112 may wrap around a transversal portion of the nanoribbon 104 and the gate electrode material 108 may wrap around the gate dielectric material 112.

The gate electrode material 108 may include at least one P-type work function metal or N-type work function metal, depending on whether the transistor 110 is a PMOS transistor or an NMOS transistor (P-type work function metal used as the gate electrode material 108 when the transistor 110 is a PMOS transistor and N-type work function metal used as the gate electrode material 108 when the transistor 110 is an NMOS transistor). For a PMOS transistor, metals that may be used for the gate electrode material 108 may include, but are not limited to, ruthenium, palladium, platinum, cobalt, nickel, and conductive metal oxides (e.g., ruthenium oxide). For an NMOS transistor, metals that may be used for the gate electrode material 108 include, but are not limited to, hafnium, zirconium, titanium, tantalum, aluminum, alloys of these metals, and carbides of these metals (e.g., hafnium carbide, zirconium carbide, titanium carbide, tantalum carbide, and aluminum carbide). In some embodiments, the gate electrode material 108 may include a stack of two or more metal layers, where one or more metal layers are work function metal layers and at least one metal layer is a fill metal layer. Further layers may be included next to the gate electrode material 108 for other purposes, such as to act as a diffusion barrier layer or/and an adhesion layer.

In some embodiments, the gate dielectric material 112 may include one or more high-k dielectrics including any of the materials discussed herein with reference to the insulator material that may surround portions of the transistor 110. In some embodiments, an annealing process may be carried out on the gate dielectric material 112 during fabrication of the transistor 110 to improve the quality of the gate dielectric material 112. The gate dielectric material 112 may have a thickness that may, in some embodiments, be between about 0.5 nanometers and 3 nanometers, including all values and ranges therein (e.g., between about 1 and 3 nanometers, or between about 1 and 2 nanometers). In some embodiments, the gate stack 106 may be surrounded by a gate spacer, not shown in FIG. 1. Such a gate spacer would be configured to provide separation between the gate stack 106 and source/drain contacts of the transistor 110 and could be made of a low-k dielectric material, some examples of which have been provided above. A gate spacer may include pores or air gaps to further reduce its dielectric constant.

Turning to the S/D regions 114 of the transistor 110, in some embodiments, the S/D regions may be highly doped, e.g., with dopant concentrations of about 10²¹ cm⁻³, in order to advantageously form Ohmic contacts with the respective S/D electrodes, although these regions may also have lower dopant concentrations and may form Schottky contacts in some implementations. Irrespective of the exact doping levels, the S/D regions of a transistor are the regions having dopant concentration higher than in other regions, e.g., higher than a dopant concentration in the transistor channel (i.e., in a channel material extending between the first S/D region 114-1 and the second S/D region 114-2), and, therefore, may be referred to as “highly doped” (HD) regions. Even with doped to realize threshold voltage tuning as described herein, the channel portions of transistors typically include semiconductor materials with doping concentrations significantly smaller than those of the S/D regions 114.

The S/D regions 114 of the transistor 110 may generally be formed using either an implantation/diffusion process or an etching/deposition process. In the former process, dopants such as boron, aluminum, antimony, phosphorous, or arsenic may be ion-implanted into the nanoribbon 104 to form the source and drain regions. An annealing process that activates the dopants and causes them to diffuse further into the nanoribbon 104 may follow the ion implantation process. In the latter process, portions of the nanoribbon 104 may first be etched to form recesses at the locations of the future S/D regions 114. An epitaxial deposition process may then be carried out to fill the recesses with material that is used to fabricate the S/D regions 114. In some implementations, the S/D regions 114 may be fabricated using a silicon alloy such as silicon germanium or silicon carbide. In some implementations, the epitaxially deposited silicon alloy may be doped in situ with dopants such as boron, arsenic, or phosphorous. In further embodiments, the S/D regions 114 may be formed using one or more alternate semiconductor materials such as germanium or a group III-V material or alloy. And in further embodiments, one or more layers of metal and/or metal alloys may be used to form the S/D regions 114. In some embodiments, a distance between the first and second S/D regions 114 (i.e., a dimension measured along the longitudinal axis 120 of the nanoribbon 104) may be between about 5 and 40 nanometers, including all values and ranges therein (e.g., between about 22 and 35 nanometers, or between about 20 and 30 nanometers).

The IC structure 100 shown in FIG. 1, as well as IC structures shown in other drawings of the present disclosure, is intended to show relative arrangements of some of the components therein, and the IC structure 100, or portions thereof, may include other components that are not illustrated (e.g., electrical contacts to the S/D regions 114 of the transistor 110, additional layers such as a spacer layer around the gate electrode of the transistor 110, etc.). For example, although not specifically illustrated in FIG. 1, a dielectric spacer may be provided between a first S/D electrode (which may also be referred to as a “first S/D contact”) coupled to a first S/D region 114-1 of the transistor 110 and the gate stack 106 as well as between a second S/D electrode (which may also be referred to as a “second S/D contact”) coupled to a second S/D region 114-2 of the transistor 110 and the gate stack 106 in order to provide electrical isolation between the source, gate, and drain electrodes. In another example, although not specifically illustrated in FIG. 1, at least portions of the transistor 110 may be surrounded in an insulator material, such as any suitable interlayer dielectric (ILD) material. In some embodiments, such an insulator material may be a high-k dielectric including elements such as hafnium, silicon, oxygen, titanium, tantalum, lanthanum, aluminum, zirconium, barium, strontium, yttrium, lead, scandium, niobium, and zinc. Examples of high-k materials that may be used for this purpose may include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate. In other embodiments, the insulator material surrounding portions of the transistor 110 may be a low-k dielectric material. Some examples of low-k dielectric materials include, but are not limited to, silicon dioxide, carbon-doped oxide, silicon nitride, organic polymers such as perfluorocyclobutane or polytetrafluoroethylene, fused silica glass (FSG), and organosilicates such as silsesquioxane, siloxane, or organosilicate glass.

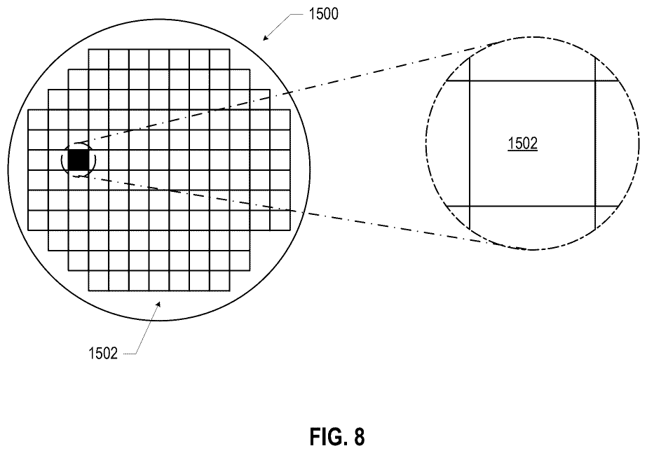

Implementations of the present disclosure may be formed or carried out on any suitable support structure, such as a substrate, a die, a wafer, or a chip. The support structure may, e.g., be the wafer 1500 of FIG. 8, discussed below, and may be, or be included in, a die, e.g., the singulated die 1502 of FIG. 8, discussed below. The support structure may be a semiconductor substrate composed of semiconductor material systems including, for example, N-type or P-type materials systems. In one implementation, the semiconductor substrate may be a crystalline substrate formed using a bulk silicon or a silicon-on-insulator (SOI) substructure. In other implementations, the semiconductor substrate may be formed using alternate materials, which may or may not be combined with silicon, that include, but are not limited to, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide, or other combinations of group III-V materials (i.e., materials from groups III and V of the periodic system of elements), group II-VI (i.e., materials from groups II and IV of the periodic system of elements), or group IV materials (i.e., materials from group IV of the periodic system of elements). In some embodiments, the substrate may be non-crystalline. In some embodiments, the support structure may be a printed circuit board (PCB) substrate. Although a few examples of materials from which the support structure may be formed are described here, any material that may serve as a foundation upon which an IC structure with nanoribbon-based transistors and an etch stop layer below the nanoribbons as described herein may be built falls within the spirit and scope of the present disclosure.

As further shown in FIG. 1, the IC structure 100 includes a replacement structure 102 between the transistor 110 and the support 101. The replacement structure 102 may be what was originally a subfin made of the semiconductor material of the nanoribbon 104 and, optionally, of an upper portion of the support 101. An opening in the IC structure 100 formed by the removal of the subfin may subsequently be filled with any suitable material, e.g., an insulator material, thus forming the replacement structure 102. The support 101 is shown in FIG. 1 with a dotted outline to illustrate that, in one scenario, it may be a support structure as described above over which the nanoribbon 104 may be originally provided. In another scenario, the dotted outline of the support 101 is used to represent that the support 101 may be any other structure to which the transistor 110 and the replacement structure 102 may be attached after the original support structure is removed and the subfin is replaced with the replacement structure 102. For example, in some embodiments according to this scenario, the support 101 may be a carrier substrate, a package substrate, an interposer, or another die.

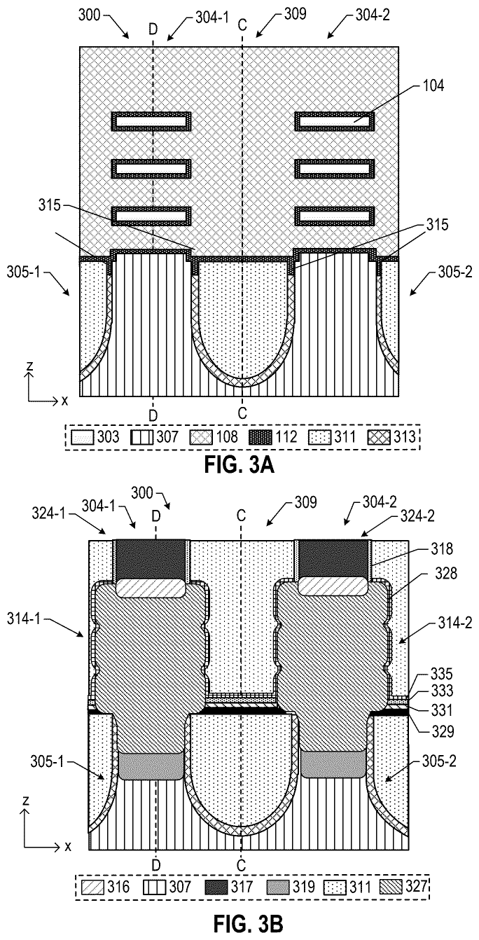

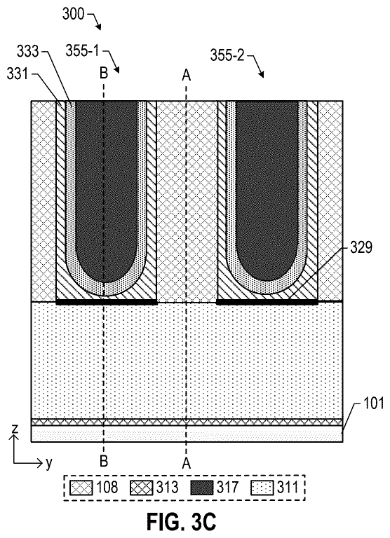

Although only one nanoribbon 104 is shown in FIG. 1, the IC structure 100 may include a plurality of such nanoribbons 104 stacked above one another, e.g., as is shown in FIG. 3A showing an IC structure 300 which may be one example of the IC structure 100.

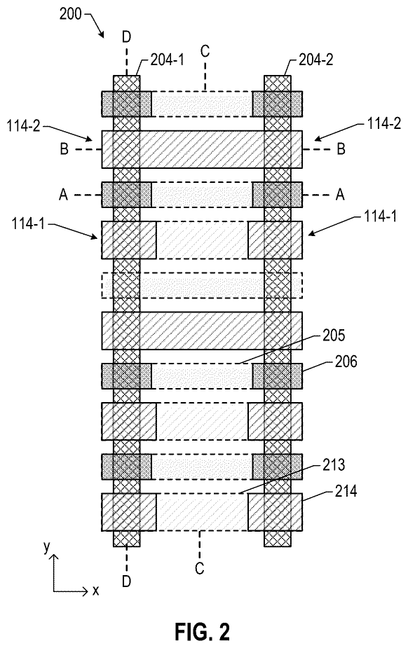

FIG. 2 is a top-down view of an IC device 200 fabricated using techniques to reduce a gated subfin in a nanoribbon-based transistor, according to one embodiment of the present disclosure. Some of the materials are not shown in the top-down view in order to not obscure the drawing.

As shown in FIG. 2, the IC device 200 may include two nanoribbon stacks 204-1 and 204-2 (collectively referred to as “nanoribbon stacks 204”), if the transistors to be implemented in the IC device 200 are nanoribbon transistors such as the one illustrated in FIG. 1. Alternatively, what is now shown as nanoribbon stacks 204-1 and 204-2 could be fins, if the transistors to be implemented in the IC device 200 are FinFETs. The nanoribbon stacks 204 may include stacks of one or more nanoribbons 104 as described above, and may be provided over a support such as the support 101 (not specifically shown in FIG. 2). The nanoribbon stacks 204 may extend substantially parallel to one another, e.g., along the y-axis of the coordinate system 105, consistent with the illustration of FIG. 1. Metal gate lines 205 (shown in FIG. 2 to be within dashed contours) and S/D contact lines 213 may extend substantially perpendicular to the nanoribbon stacks 204 and substantially parallel to one another, e.g., along the x-axis of the coordinate system 105. FIG. 2 illustrates that the metal gate lines 205 and the S/D contact lines 213 may be provided in an alternating manner. Metal gate lines 205 may intersect the gate contacts 206 that are in conductive contact with the gate stacks 106 (which are underneath the gate contacts 206 and, therefore, not seen in the view of FIG. 2) provided over channel portions of the nanoribbon stacks 204, providing electrical connectivity to the gates of the nanoribbon transistors. Thus, portions of the gate contacts 206 intersecting the gate stacks 106 are in conductive contact with the gate stacks 106 and serve as gate contacts for the transistors. Similarly, S/D contact lines 213 may intersect the S/D contacts 214 provided over S/D regions 114 (which are underneath the S/D contacts 214 and, therefore, not seen in the view of FIG. 2) of the nanoribbon stacks 204, providing electrical connectivity to the S/D regions 114 of the nanoribbon transistors. Thus, portions of the S/D contacts 214 intersecting the S/D regions 114 are in conductive contact with the S/D regions 114 and serve as S/D contacts for the transistors.

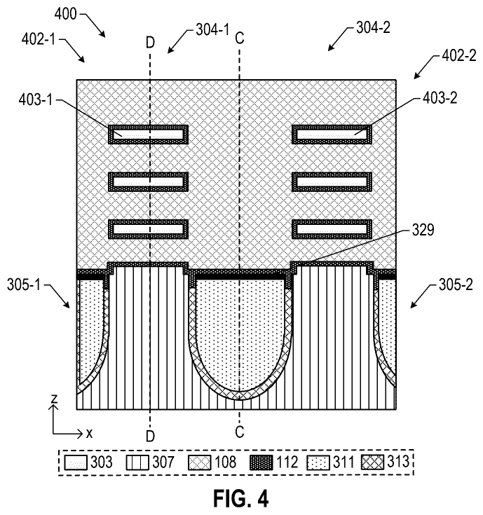

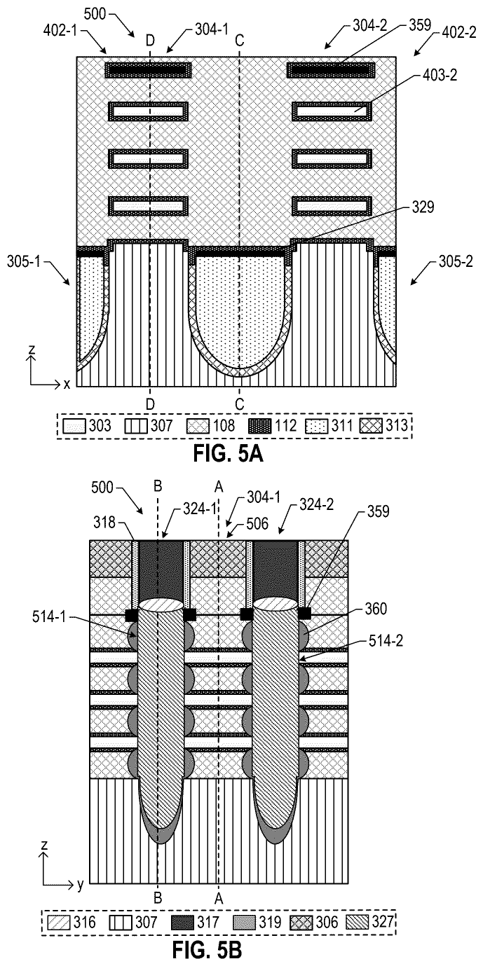

FIGS. 3A-3C, 4, and 5A-5B are cross-sectional views of IC structures such as the device 200 of FIG. 2, according to different embodiments of the present disclosure. In particular, FIGS. 3A-3C illustrate different cross-sectional views of an example IC structure 300 with a nitride-based film over the STI between nanoribbon stacks in a plane with S/D regions in the nanoribbon stacks. FIG. 4 illustrates a cross-sectional view of another example IC structure 400 where the nitride-based film is present over the STI in a plane with gate/channel regions in the nanoribbons stacks. FIGS. 5A-5B illustrate cross-sectional views of another example IC structure 500 in which a nitride-based film is also present over the nanoribbon stacks.

Turning first to FIG. 3A, the IC structure 300 illustrates a cross-section of two adjacent stacks of nanoribbons 304-1, 304-2 fabricated with techniques to reduce gated subfins. FIG. 3A illustrates a cross-sectional view of the IC structure 300 in an x-z plane cut along adjacent fins from which the nanoribbon stacks 304-1, 304-2 are formed, such as the plane AA shown in FIG. 2. The IC structure 300 includes transistors similar to the transistor 110 but built on the basis of nanoribbon stacks 304-1 of a plurality of nanoribbons 104 instead of just one nanoribbon 104 as shown in FIG. 1. While three nanoribbons 104 are shown to be included in the nanoribbon stacks 304-1, 304-2, in other embodiments, fewer nanoribbons 104 or more nanoribbons 104 may be included (e.g., two nanoribbons, four nanoribbons, etc.). FIG. 3A illustrates a semiconductor material 303 as the material of the nanoribbons 104. The IC structure also includes subfins 305-1, 305-2, including a first subfin 305-1 below and substantially aligned with the first stack of nanoribbons 304-1 and a second subfin 305-2 below and substantially aligned with the second stack of nanoribbons 304-2. The subfins 305-1, 305-2 in FIG. 3A are shown as including subfin replacement structures of an insulator material 307; however, in other examples, the subfins 305-1, 305-2 may include subfin structures that include the semiconductor material 303 below the nanoribbon stacks 304-1, 304-2, and/or include semiconductor materials of different material compositions. A gate stack having a gate insulator material 112 and a gate electrode material 108 wraps around channel portions of the nanoribbons 104.

The two stacks of nanoribbons 304-1, 304-2 are separated by a region 309, which includes an insulator material 311 (e.g., an STI) between and coplanar with the first subfin 305-1 and the second subfin 305-2. Note that although FIG. 3A illustrates the two nanoribbon stacks 304-1, 304-2 as being electrically coupled with the same continuous portion of the gate electrode material 108, in other examples, an isolation structure including an insulator material may be present between the two nanoribbon stacks 304-1, 304-2. In the example illustrated in FIG. 3A, another insulator material 313 lines the STI region between the subfins 305-1, 305-2. In some examples, the insulator material 311 and the insulator material 313 may be an oxide (e.g., silicon oxide, silicon oxynitride, carbon-doped silicon oxide, carbon-doped silicon oxynitride, or another suitable insulator material including oxygen), and may have substantially the same or different material compositions. As can be seen in FIG. 3A, the STI region between the subfins includes a continuous portion of the insulator material 311 between the subfins 305-1, 305-2 in a plane below the nanoribbons stacks 304-1, 304-2 (e.g., below a bottom nanoribbon of the stacks 304-1, 304-2). As mentioned briefly above, during fabrication, the insulator material 311 may be susceptible to recession during various processes. In some cases, the recession of the STI is significant and can result in the gate electrode material 108 being deposited in recessed areas between the subfins 305-1, 305-2, resulting in a gated subfin. In contrast to some conventional IC structures that may include a significant gated subfin portion, a layer of an insulator material having a different material composition than the STI, such as a nitride-based film where the STI is an oxide, can minimize recession of the STI, and thus minimize or even eliminate a gated portion of the subfins.

In the example illustrated in FIG. 3A, a nitride-based film, which was provided over the insulator material 311 between the nanoribbon stacks 304-1, 304-2, has been removed and is no longer present in the cross-section shown in FIG. 3A as a result of one or more etching and/or cleaning processes. However, as a result of using the nitride-based film to protect the insulator material 311, the insulator material 311 between the subfins 305-1, 305-2 experienced minimal recession, which prevented exposure of the sides of the subfins 305-1, 305-2 and thus prevented the gate electrode material 108 from wrapping around portions of the subfins 305-1, 305-2. Thus, the gate electrode material 108 is substantially absent from between the subfins 305-1, 305-2. In one example, a layer of the gate dielectric material 112 may be present over the insulator material 311. In the example illustrated in FIG. 3A, the gate dielectric material 112 may also be present in slightly recessed areas 315 along the sides of the subfins 305-1, 305-2 between the insulator material 311 and the insulator material 307 of the subfin structures. In one such example, the presence of the gate dielectric material 112 and the absence of the gate electrode material 108 below the layer of gate dielectric material 112 (e.g., below the gate dielectric material 112 over or on the insulator material 311) may indicate the use of a film to protect the STI. In accordance with some examples, although the nitride-based film may not be present in the final IC structure in the fin-cut, the nitride-based film may be present in some cross-sectional views that cut along the source or drain regions of transistors in the nanoribbons stacks 304-1, 304-2.

For example, FIG. 3B illustrates an example cross-sectional view of the IC structure 300 along an x-z plane cut along source or drain regions in the adjacent nanoribbon stacks 304-1, 304-2, such as the plane BB shown in FIG. 2. FIG. 3B illustrates a first S/D region 314-2 in the first nanoribbon stack 304-1 and a second S/D region 314-2 in a second nanoribbon stack 304-2. The S/D regions 314-1, 314-2 represent regions of a doped semiconductor material 327, and may be examples of the S/D regions 114 discussed above. Although the S/D regions 314-1 and 314-2 are illustrated as including the same doped semiconductor material 327, in some examples, the S/D regions 314-1 and 314-2 may have a different material composition. In one example, the first S/D region 314-1 is either a source region or a drain region of a first nanoribbon transistor formed in the first nanoribbon stack 304-1, and the second S/D region 314-2 is either a source or a drain region of a second nanoribbon transistor formed in the second nanoribbon stack 304-2. In some examples, an isolation region extending into the insulator material 311 in the subfin region may be formed by etching an opening between the S/D regions 314-1, 314-2 and filing the opening with an insulator material. In the example illustrated in FIG. 3B, an insulator material 319 is present at a bottom of the S/D regions 314-1, 314-2. Although not visible in the cross-section illustrated in FIG. 3B, in one example the insulator material 319 separates the S/D regions 314-1, 314-2 from the gate electrode material 108. The insulator material 319 may include any of the insulator materials described herein, e.g., any of the ILD materials described above. In other examples, the insulator material 319 may not be present at the bottom of the S/D regions 314-1, 314-2 in the final IC structure.

The IC structure 300 includes S/D contacts 324-1, 324-2 that include a conductive material 317 for making electrical contact with the S/D regions 114-1, 114-2. FIG. 3B illustrates an IC structure 300 with front-side contact structures, however, in other examples, one or more contact structures may be formed from a back side of the wafer or IC structure. The S/D contacts 324-1, 324-2 may be electrically isolated from surrounding materials by gate spacers 318, which may include any suitable insulator material to electrically isolate the S/D contacts 324-1, 324-2 from the gate contact. At the bottom of the S/D contacts 324-1, 324-2, an interface material 316 may be deposited to provide an interface between the S/D regions 114-2 and the electrically conductive fill material 317 of S/D contacts 324-1, 324-2. The interface material 316 may include/be a metal such as titanium which, once deposited, may intermix with the material of the S/D regions 114, e.g., with silicon, forming a compound (e.g., titanium silicide) that may help reduce contact resistance of the S/D contacts 214.

In the example illustrated in FIG. 3B, a nitride-based film 329 is present over the insulator material 311 between the S/D regions 314-1, 314-2 in adjacent nanoribbon stacks 304-1, 304-2. Thus, although the nitride-based film 329 in the cut shown in FIG. 3A may have been removed as a result of etching and/or cleaning processes, the nitride-based film 329 may remain in a plane intersecting the S/D regions 314-1, 314-2. For example, the first region 314-1 of a doped semiconductor material in the first stack 304-1 of nanoribbons and the second region 314-2 of a doped semiconductor material in the second stack 304-2 of nanoribbons are in a plane that is orthogonal to the substrate (e.g., in an x-z plane as shown in FIG. 3B). A first subfin structure (e.g., the subfin 305-1) is below and substantially aligned with the first stack 304-1 of nanoribbons and a second subfin structure (e.g., the subfin 305-2) is below and substantially aligned with the second stack 304-2 of nanoribbons, and the insulator material 311 is between and coplanar with the first subfin structure and the second subfin structure. The IC structure 300 includes the nitride-based film 329 on the insulator material 311 in the plane (e.g., directly on and in direct physical contact with the insulator material 311 such that there is not an intervening layer between the nitride-based film 329 and the insulator material 311). In one example, the nitride-based film 329 is or includes silicon nitride (SiN). In various examples, the nitride-based film 329 may include SiN, SiON, TiON, or TiN. In some examples, the nitride-based film 329 may have a thickness in a range of about 3-10 nanometers or about 4-8 nanometers, wherein the thickness is a dimension of the nitride-based film 329 in a plane substantially orthogonal to the nanoribbons (and substantially orthogonal to a substrate over which the nanoribbons stacks 304-1, 304-2 are disposed).

One or more additional layers may be present over the nitride-based film 329. For example, the example in FIG. 3B illustrates layers 331, 333, and 335 over the nitride-based film 329. In one example, the layers 331, 333, and 335 may include one or more of a barrier layer, insulator layer, and etch stop layer. In one such example, the layer 331 is on (e.g., is in direct contact with) the nitride-based film 329, and includes SiO2, SiOC, or another suitable insulator material having a different material composition than the nitride-based film 329. Thus, in the example illustrated in FIG. 3B, the IC structure 300 includes the nitride-based film 329 on the insulator material 311, and an oxide film (e.g., the layer 331) on the nitride-based film 329. In an example in which the nitride-based film 329 was absent, the insulator material 311 may be significantly recessed due to the absence of the nitride-based film 329, and the layer 331 may be directly on the insulator material 311. In the example illustrated in FIG. 3B, the layer 333 may include an insulator material having a different material composition than the layer 331. In one example, the layer 333 includes SiOCN, SiON, or another insulator material having a different material composition than the layer 331. In some examples, the layer 333 also has a different material composition than the nitride-based film 329. In some examples, the layer 333 and the nitride-based film 329 may have substantially the same material composition (e.g., both the nitride-based film 329 and the layer 333 may include an oxynitride such as SiON). However, in one such example, the layer 333 would have been deposited in a later process in the fabrication of the IC structure 300 than the nitride-based film 329, and is thus present over the layer 331 (rather than on the insulator material 311) and may not provide protection to the insulator material 311 from unintentional recession during the earlier clean and etch processes.

The layer 335 may include an insulator material having a different material composition than the layers 333 and 331. In one example, the layer 335 includes SiN, or another suitable insulator material having a different material composition than the layers 333 and 331. In some examples, the layer 335 may have a different material composition than the nitride-based film 329. In other examples, the layer 335 and the nitride-based film may have the same material composition (e.g., both the layer 335 and the nitride-based film may be SiN). However, in one such example, the layer 335 and the nitride-based film 329 are deposited at different times and thus may be distinguishable by their location in the IC structure 300. For example, in FIG. 3B, the layer 335 wraps around the regions 314-1, 314-2 of doped semiconductor material in addition to being present over the insulator material 311, and the nitride-based film is limited to the region over the STI between the regions 314-1, 314-2 of doped semiconductor material. Thus, in the example illustrated in FIG. 3B, the IC structure 300 may include the nitride-based film 329 (e.g., SiN, SiON, TiN, or TION) over the insulator material 311, an oxide-based film (e.g., the layer 331, such as SiO₂ or SiOC) over the nitride-based film 329, an oxynitride film (e.g., the layer 333, such as SiOCN or SiON) over the oxide-based film, and another nitride-based film (e.g., the layer 335, such as SiN) over the oxynitride film, where the other nitride-based film is present on and around the S/D regions 314-1, 314-2. FIG. 3B also illustrates the insulator material 311 between the S/D regions 314-1, 314-2 and between the contacts 324-1, 324-2, however, the insulator material between the regions 314-1, 314-2 may include the same or a different material than the insulator material 311 between the subfins 305-1, 305-2.

FIG. 3C illustrates another cross-section of the IC structure 300 along a y-z plane in a cut between adjacent nanoribbon stacks, such as the plane CC shown in FIG. 2. As can be seen in the perspective shown in FIG. 3C, the nitride-based film 329 is present in the regions 355-1, 355-2 between S/D regions in the adjacent nanoribbon stacks 304-1, 304-2. In the example illustrated in FIG. 3C, the layer 331 is over the nitride-based film 329, and the layer 333 is over the layer 331 in a plane (e.g., the plane BB shown in FIGS. 2 and 3C) orthogonal to the support 101 that intersects a first S/D region 314-1 in a first nanoribbon stack 304-1 and a second S/D region 314-2 in a second nanoribbon stack 304-2. In the cross-section illustrated in FIG. 3C, the layer 335 is absent (e.g., removed as a result of processing, such as the metallization of the S/D contacts). Thus, in one example, the conductive material 317 is over the layer 333. In one example, the conductive material 317 is directly on (e.g., in contact with) the layer 333, the layer 333 is directly on the layer 331, and the layer 331 is directly on the nitride-based film 329.

FIG. 4 illustrates a cross-section of another IC structure 400 of two adjacent stacks of nanoribbons 304-1, 304-2 fabricated with techniques to reduce gated subfins. The IC structure 400 is similar to the IC structure 300 of FIG. 3A, but differs from the IC structure 300 in that at least a portion of the nitride-based film 329 is still present in the final IC structure in a plane with the gate or channel regions in the adjacent nanoribbon stacks 304-1, 304-2. For example, the IC structure 400 includes a first gate structure 402-1 including a gate electrode material 108 around first portions 403-1 of first nanoribbons of the stack 304-1 of nanoribbons, and a second gate structure 402-2 including the gate electrode material 108 around second portions 403-2 of second nanoribbons of the second stack 304-2, where the first gate structure 402-1 and the second gate structure 402-2 are in a plane (e.g., an x-z plane such as the plane AA shown in FIG. 2) that is substantially orthogonal to the substrate, and the nitride-based film 329 is present over the insulator material 311 in the plane. In some example in which the nitride-based film 329 is present in a plane with the gate regions, such as shown in FIG. 4, the nitride-based film 329 in a plane with the gate regions may be thinner than the nitride-based film 329 in a plane with the S/D contact regions (e.g., due to etching of the nitride-based film 329 in a plane with the gate structures 402-1, 402-2).

FIGS. 5A-5B illustrate a cross-section of another IC structure 500 fabricated with techniques to reduce gated subfins, in which a nitride-based film is present over the nanoribbon stacks in addition to a nitride-based film over the STI. As can be seen in FIG. 5A, a nitride-based film 359 is present over the nanoribbon stack 304-1 and over the nanoribbon stack 304-2 in addition to a nitride-based film 329 over the insulator material 311. In the example illustrated in FIG. 5A, the nitride-based film 359 over the top nanoribbons of the stacks 304-1, 304-2 are substantially aligned with the stacks 304-1, 304-2. In one example, the nitride-based film 359 over the nanoribbon stacks may have a width that is about the same as a width of a nanoribbon of the stack, where the width is a dimension of the nitride-based film 359 in a plane substantially parallel to the substrate (e.g., along an axis corresponding to the width of the nanoribbons). In another example, the width of the nitride-based film 359 may be slightly larger than the width of the nanoribbons (e.g., as a result of the process used to form the nitride-based film 359, as explained in more detail below). In the example illustrated in FIG. 5A, the nitride-based film 359 is surrounded by the gate dielectric material 112, which is surrounded by the gate electrode material 108.

FIG. 5B illustrates another cross-sectional view of the IC structure 500. FIG. 5B illustrates an example cross-sectional view of the IC structure 500 in the y-z plane cut along channel regions in one of the nanoribbon stacks, such as the plane DD shown in FIG. 2. FIG. 5B illustrates a first S/D region 514-1 and a second S/D region 514-2 extending through the nanoribbon stack 304-1, electrically insulated/separated from the gate electrode material 108 by the insulator material 319. In some embodiments, the insulator material 319 may form so-called “dimples” 360 in areas where the insulator material 319 separates the S/D regions 514-1, 514-2 from the gate electrode material 108. Above the nanoribbon stack 304-1, FIG. 5A illustrates a gate contact 506 and S/D contacts 324-1, 324-2 on either side of the gate contact 506. The gate contact 506 may include an electrically conductive material 306 in electrically conductive contact with the gate electrode material 108. In various embodiments, material compositions of the electrically conductive material 306 and the gate electrode material 108 may be substantially the same or different.

As can be seen in FIG. 5B, the nitride-based film 359 may be present over the nanoribbons on either side of the S/D regions 514-1, 514-2 of a transistor formed in one of the stacks of nanoribbons. In the example illustrated in FIG. 5B, the nitride-based film 359 is in a layer or plane over the top dimple 360. In one example, the nitride-based film 359 is between the dimples 360 and the gate spacers 318 (and or other materials lining the S/D contacts 324-1, 324-2).

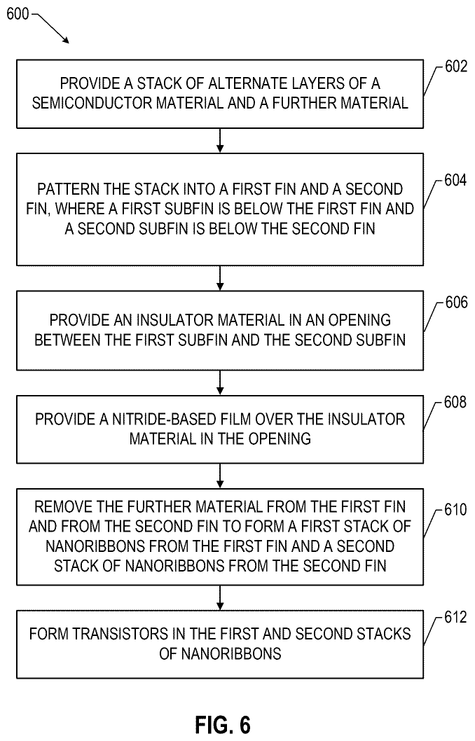

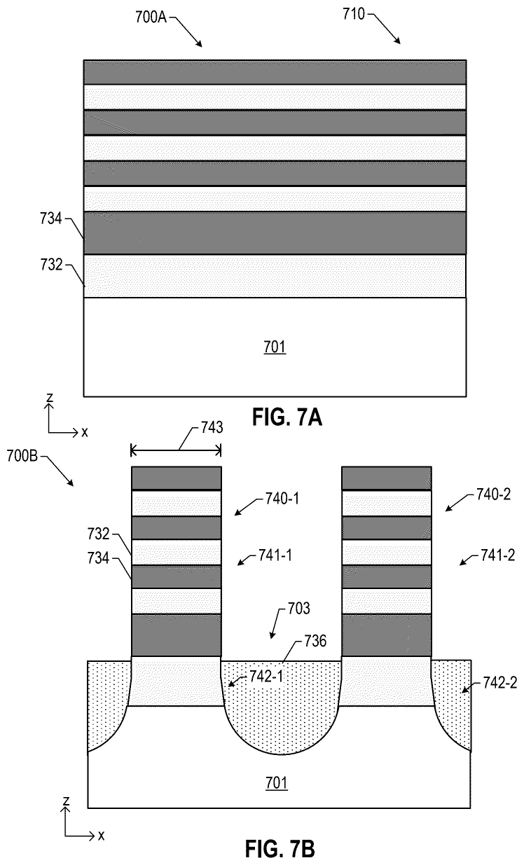

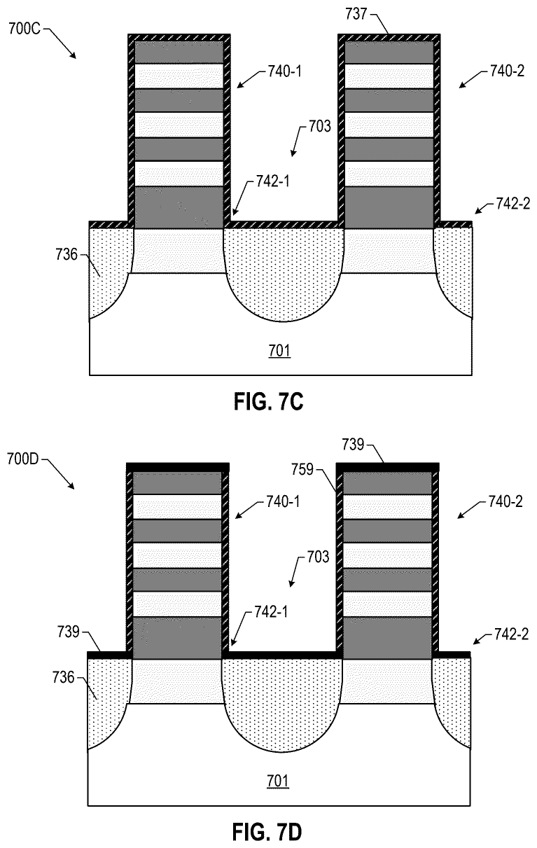

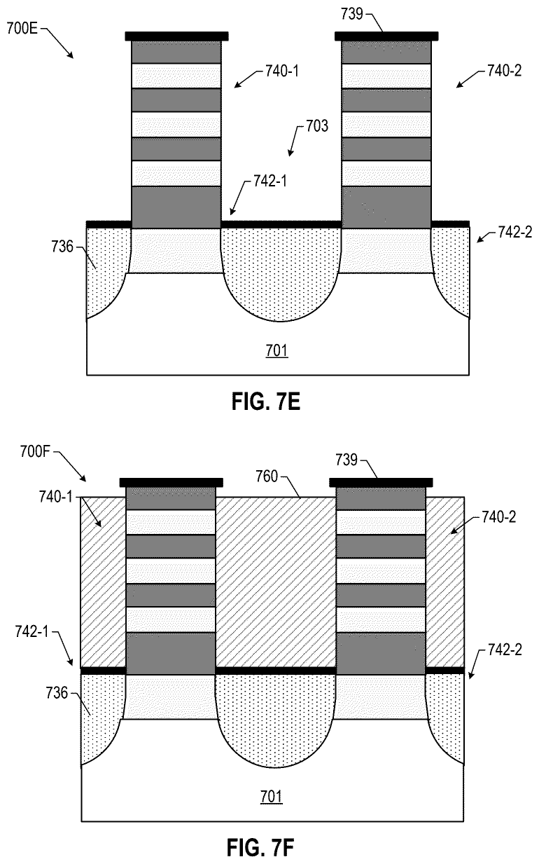

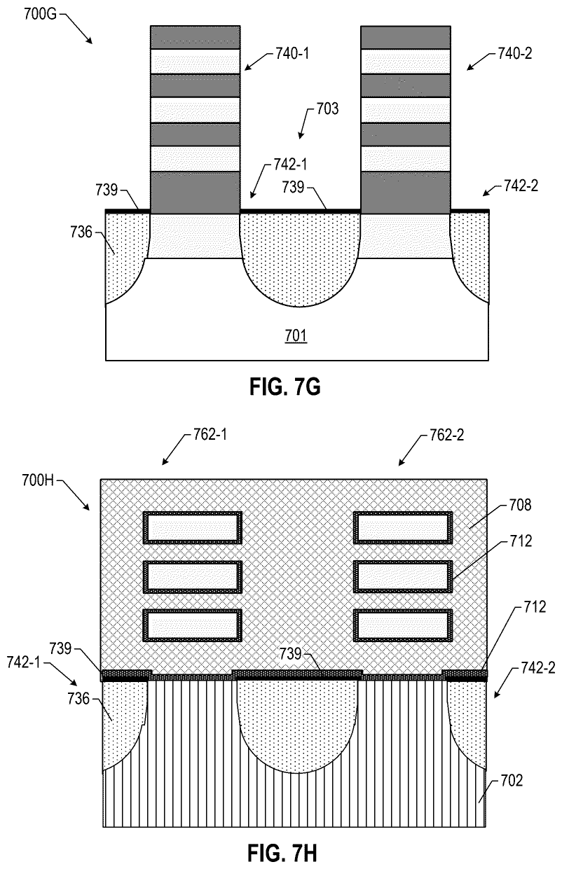

FIG. 6 is a flow diagram of an example method 600 for fabricating an IC structure using techniques to reduce a gated subfin in a nanoribbon-based transistor. FIGS. 7A-7H provide cross-sectional side views at various stages in the fabrication of an example IC structure according to the method of FIG. 6, in accordance with some embodiments. Although the operations of the method of FIG. 6 are illustrated once each and in a particular order, the operations may be performed in any suitable order and repeated as desired. For example, one or more operations may be performed in parallel to fabricate multiple IC structures using techniques to reduce a gated subfin in a nanoribbon-based transistor substantially simultaneously. In another example, the operations may be performed in a different order to reflect the structure of an IC device in which techniques to reduce a gated subfin in a nanoribbon-based transistor will be implemented.

In addition, the example fabricating methods of FIG. 6 may include other operations not specifically shown in FIG. 6, such as various cleaning or planarization operations as known in the art. For example, in some embodiments, a support, as well as layers of various other materials subsequently deposited thereon, may be cleaned prior to, after, or during any of the processes of the methods described herein, e.g., to remove oxides, surface-bound organic and metallic contaminants, as well as subsurface contamination. In some embodiments, cleaning may be carried out using e.g., a chemical solutions (such as peroxide), and/or with ultraviolet (UV) radiation combined with ozone, and/or oxidizing the surface (e.g., using thermal oxidation) then removing the oxide (e.g., using hydrofluoric acid (HF)). In another example, the intermediate IC structures described herein may be planarized prior to, after, or during any of the processes of the method of FIG. 6 described herein, e.g., to remove overburden or excess materials. In some embodiments, planarization may be carried out using either wet or dry planarization processes, e.g., planarization be a chemical mechanical planarization (CMP), which may be understood as a process that utilizes a polishing surface, an abrasive and a slurry to remove the overburden and planarize the surface.

Turning to FIG. 6, the method 600 begins with a process 602 of providing a stack of alternate layers of a semiconductor material and a further material. The IC structure 700A of FIG. 7A is an example resulting structure of the process 602. The IC structure 700A includes a substrate 701 and alternating layers of a semiconductor material 732 and layers of a further material 734. While FIG. 7A illustrates four layers of the semiconductor material 732 and four layers of the further material 734 in a stack 710, in other embodiments, any other number of layers may be used as long as they are alternating and include at least three layers of the semiconductor material 732 and at least two layers of the further material 734. The upper layers of the semiconductor material 732 will later be formed into nanoribbons stacked above one another, as shown in FIGS. 3A-3C, 4, and 5A-5B, discussed below. Thus, although a particular number of nanoribbons formed of the upper layers of the semiconductor material 732 is depicted in FIGS. 3A-3C, 4, and 5A-5B (namely, three nanoribbons) and subsequent drawings, embodiments of the present disclosure include IC structures having more or fewer stacked nanoribbons than depicted. As shown in FIG. 7A, in some embodiments, the alternation of layers of the semiconductor material 732 and the further material 734 may begin after a bottom layer of the semiconductor material 732 is provided over the substrate 701. In one such example, the bottom layer may later form a subfin under the stack of nanoribbons. Although the thickness of the bottom layer of the semiconductor material 732 is depicted as being greater than the subsequent layers of the semiconductor material 732 that are formed into nanoribbons via further processing, in other examples, the bottom layer may have a substantially same thickness as another layer of the semiconductor material 732.

The semiconductor material 732 may be any of the semiconductor/channel materials described above with reference to the nanoribbons 104 of FIG. 1 and the nanoribbons of the stacks 204-1, 204-2 of FIG. 2. The further material 734 may be any suitable material that is etch-selective with respect to the semiconductor material 732 so that, in a later process, the second material 734 may be etched away to form nanoribbons of the semiconductor material 732. As known in the art, two materials are said to be “etch-selective” (or said to have “sufficient etch selectivity”) with respect to one another when etchants used to etch one material do not substantially etch the other, enabling selective etching of one material but not the other. For example, in some embodiments, the semiconductor material 732 may be silicon while the second material 734 may be a second semiconductor material such as silicon germanium. In another example, the semiconductor material 732 may be silicon germanium, while the second material 734 may be silicon. In other examples, the second material may be made of a non-semiconductor material, e.g., of an insulator material, as long as this material is sufficiently etch-selective with respect to the semiconductor material 732.

Thus, the material 734 may be any suitable sacrificial material that is etch-selective with respect to the semiconductor material 732. Selecting the material 734 to be a semiconductor material may be particularly advantageous because it may improve quality of the semiconductor material 732 if the semiconductor material 732 is epitaxially grown on the material 734. In some embodiments, the process 602 may include epitaxially growing layers of the semiconductor material 732 and the further material 734 (e.g., a second semiconductor material) in an alternating manner. In other embodiments, alternate layers of the semiconductor material 732 and the further material 734 may be provided in the process 602 using other techniques, such as layer transfer or thin-film deposition. Although FIG. 7A illustrates the same semiconductor material 732 in various layers of the IC structure 700A, in general, material compositions of a semiconductor material from which nanoribbons will later be formed in different layers of the IC structure 700A may be different. For example, the semiconductor material 732 of one layer of the IC structure 700A may be silicon while the semiconductor material 732 of another layer of the IC structure 400A may be a III-N semiconductor material such as GaN.

Turning again to FIG. 6, the method 600 continues with the process 604 of patterning the stack into a first fin and a second fin, where a first subfin is below the first fin and a second subfin is below the second fin. The method 600 also involves the process 606 of providing an insulator material (e.g., STI) in an opening between the first subfin and the second subfin. The IC structure 700B of FIG. 7B is an example resulting structure of the processes 604 and 606. The IC structure 700B illustrates that the stack 710 of alternating layers of the semiconductor material 732 and the further material 734 has been patterned into a first fin 740-1 and a second fin 740-2 that are separated by an opening 703. Each of the fins 740-1, 740-2 may include an active portion (e.g., the active portions 741-1, 741-2) and a subfin portion (e.g., the subfin portions 742-1, 742-2). The active portions 741-1, 741-2 may be portions of the fins 740-1, 740-2 from which later the respective nanoribbons will be formed, while the subfin portions 742-1, 742-2 are portions of the fins 740-1, 740-2 that have sidewalls that will be at least partially enclosed with an insulator material 736, e.g., as shown in FIG. 7B. The insulator material 736 may include any of insulator material typically used as an STI in fin-based or nanoribbon-based transistors, e.g., any suitable low-k dielectric material or other suitable insulator material.

Thus, the fins 740-1, 740-2 may be shaped as structures that extend away from the substrate 701 and may include subfins 742-1, 742-2 at the bottom, the subfins 742-1, 742-2 being the portions of the fins 740-1, 740-2 that are at least partially enclosed by an insulator material 736. In some embodiments, the subfins 742-1, 742-2 may include the bottom layer of the semiconductor material deposited at process 602, as well as an upper portion of the substrate 701, as is shown in FIG. 7B. However, in other embodiments, the semiconductor material 732 of the subfins 742-1, 742-2 and/or some or all of the substrate 701 may be removed and/or replaced with one or more other materials in subsequent processes.

In some embodiments, the fins 740-1, 740-2 may have a width 743 (i.e., a dimension of the fins 740-1, 740-2 measured along the x-axis of the example coordinate system shown in FIG. 7B). The width 743 may be that of the width of the nanoribbons subsequently formed (e.g., the nanoribbon 204 of FIG. 2 described above). The fins 740-1, 740-2 may further have a length (i.e., a dimension of the fins 740-1, 740-2 measured along the y-axis of the example coordinate system shown in FIG. 7B, where the y-axis is going into and coming out of the page) suitable to account for the length of the future nanoribbons (e.g., as described above with reference to the length of the nanoribbon 204 of FIG. 2).

In various embodiments, any suitable patterning techniques may be used in the process 604 to form the fins 740-1, 740-2, such as, but not limited to, photolithographic or electron-beam (e-beam) patterning, possibly in conjunction with a suitable etching technique, e.g., a dry etch, such as e.g., RF reactive ion etch (RIE) or inductively coupled plasma (ICP) RIE. In some embodiments, the etch performed in the process 604 may include an anisotropic etch, using etchants in a form of e.g., chemically active ionized gas (i.e., plasma) using e.g., bromine (Br) and chloride (CI) based chemistries. In some embodiments, during the etch of the process 604, the IC structure may be heated to elevated temperatures, e.g., to temperatures between about room temperature and 200 degrees Celsius, including all values and ranges therein, to promote that byproducts of the etch are made sufficiently volatile to be removed from the surface.

Turning again to FIG. 6, the method 600 continues with the process 608 of providing a nitride-based film over the insulator material in the opening. The IC structure 700C of FIG. 7C is an example resulting structure of the process 608. In the example illustrated in FIG. 7C, the IC structure 700C includes a nitride-based film 737 on sidewalls of the fins 740-1, 740-2 and on the insulator material 736 between the first subfin 742-1 and the second subfin 742-2. In other examples, the nitride-based film 737 could be selectively deposited over the insulator material 736, but not on the sidewalls or tops of the fins 740-1, 740-2. In one example, the nitride-based film is a layer of material including a nitride. In other examples, the initially deposited film may not include a nitride (e.g., the film 737 may be SiO or TiO), and may later be treated (e.g., with an implant process) to form a nitride-based film (e.g., SiON or TION). Although examples described herein refer specifically to a nitride-based film, in other examples, the film is a layer of an insulator material with a different material composition than the STI. Any suitable deposition technique may be used to deposit the nitride-based film 737 in the process 608. For example, a selective deposition technique that deposits the nitride-based film 737 only over (or primarily only over) the insulator material 736 may be used, or any suitable conformal deposition technique where the 737 is provided on all exposed surfaces. Examples of deposition techniques that may be used in the process 608 include atomic layer deposition (ALD), chemical vapor deposition (CVD), plasma enhanced CVD (PECVD), or/and physical vapor deposition (PVD) processes such as sputter.

In an example in which the nitride-based film 737 is deposited on all exposed surface (e.g., on the sidewalls of the fins 740-1, 740-2 in addition to on the insulator material 736), the method may involve a treatment to enable removal of the nitride-based film 737 on the sidewalls without removal the nitride-based film 737 over the insulator material 736. For example, the method may involve performing a vertical treatment over the insulator material 736 and over the fins 740-1, 740-2, without performing the treatment on portions of the nitride-based film 737 on the sidewalls of the fins 740-1, 740-2. The IC structure 700D of FIG. 7D is an example resulting structure of the process of treating portions of the nitride-based film 737. As can be seen in FIG. 7D, the IC structure 700D includes treated portions 739 of the nitride-based film 737 over the fins 740-1, 740-2 and over the insulator material 736 and untreated portions 759 on sidewalls of the fins 740-1, 740-2. The treatment may involve a process to change the characteristics of the nitride-based film 737 of the insulator material 736 (e.g., to make it harder to), but not change the characteristics of the untreated portions on the sidewalls of the fins 740-1, 740-2. In some examples, the treatment may involve a vertical nitrogen or helium-based implant process, or other suitable technique to enable the portion of the nitride-based film 737 on the sidewalls to be more easily removed than the portion of the nitride-based film 737 over the insulator material 736.

After performing the treatment, the untreated portions 759 may be removed. The IC structure 700E of FIG. 7E is an example resulting structure of the process of removing the untreated portions 759 without removing the treated portions 739 of the nitride-based film 737. Any suitable technique may be used to remove the untreated portions 759, e.g., a wet etch processor other isotropic etch technique. After removing the untreated portions 759, the treated portions 739 of the nitride-based film remains on the top of the fins 740-1, 740-2 and on the top of the insulator material 736. In some examples, the treated portion 739 of the nitride-based film 737 over the fins 740-1, 740-2 may also be removed. In one such example, a mask (such as a carbon hard mask or other suitable mask material) may be deposited over the IC structure and recessed to expose the treated portion 739 of the nitride-based film 737 over the fins 740-1, 740-2 and protect the treated portions 739 of the nitride-based film 737 over the insulator material 736. The IC structure 700F of FIG. 7F is an example resulting structure of the process of providing a mask 760 in the opening 703 over the nitride-based film 737, where the mask 760 covers the treated portion 739 of the nitride-based film 737 over the insulator material 736 and include openings to expose treated portions 739 of the nitride-based film 737 over the fins 740-1, 740-2.

The method may then involve removing the exposed treated portions 739 of the nitride-based film 737 from over the fins 740-1, 740-2, and removing the mask (e.g., with an ashing process for removing a carbon-based hard mask or other process for removing a mask material). The IC structure 700G of FIG. 7G is an example resulting structure of the process of removing the mask. As can be seen in FIG. 7G, the mask has been removed, leaving the treated portions 739 of the nitride-based film 737 over the insulator material 736 between the subfins 742-1, 742-2.

The method may involve subsequent processes (e.g., etch and deposition processes) to form additional structures, such as S/D regions in the fins 740-1, 740-2, isolation structures, etc. For example, referring again to FIG. 6, the method 600 continues with the process 610 of removing the further material from the first fin and from the second fin to “release” the nanoribbons and form a first stack of nanoribbons from the first fin and a second stack of nanoribbons from the second fin. The method 600 continues with the process 612 of forming transistors in the first and second stacks of nanoribbons. Forming transistors in the first and second stacks of nanoribbons involves, among other processes, providing a gate insulator material around portions of the nanoribbons and depositing a gate electrode material over the gate insulator material around the nanoribbons. The IC structure 700H of FIG. 7H is an example resulting structure of the process of depositing the gate electrode material around portions of the nanoribbons. As can be seen in FIG. 7H, the IC structure 700H includes two nanoribbon stacks 762-1, 762-2, a gate dielectric material 712 around portions of nanoribbons of the stacks 762-1, 762-2, and a gate electrode material 708 around the gate dielectric material 712. As can be seen in FIG. 7H, the gate dielectric 712 is also present over the nitride-based film (e.g., the treated portion 739) over the insulator material 736. In some examples, if a portion of the nitride-based film remains over the nanoribbon stacks (such as shown in FIGS. 5A-5B), the gate dielectric material 712 may also wrap around the nitride-based film over the nanoribbon stacks. In the example shown in FIG. 7H, the IC structure also includes replacement subfin structures that include an insulator material 702.

Thus, FIG. 6 illustrates a method 600 for fabricating an IC structure using techniques to reduce a gated subfin in a nanoribbon-based transistor. Performing the method 600 may result in several features in the final IC structures that are characteristic of the use of the method 600. For example, one such feature is illustrated in an IC structure 700H shown in FIG. 7H, in which a region between the adjacent stacks 762-1, 762-2 of nanoribbons includes an insulator material 736 in a first plane below the adjacent stacks 762-1, 762-2 (e.g., below a bottom nanoribbon of the stacks). The IC structure 700H includes a film (e.g., the treated portion 739 of the nitride-based film 737) over the insulator material 736 in a second plane between the first plane and the nanoribbons stacks 762-1, 762-2, where the film has a different material composition from the insulator material 736. In the example illustrated in FIG. 7H, the film is limited, in the second plane, to the region between the adjacent stacks 762-1, 762-2 (e.g., the film is absent below the first stack 762-1 in a plane that is substantially orthogonal to the substrate, substantially parallel to a length of the nanoribbons of the first stack, and that intersects the nanoribbons of the first stack).

Thus, according to examples, the film, such as the treated portion 739 of the nitride-based film, protects the insulator material 736 between the subfin structures from one or more processes involved in forming nanoribbon transistors in the nanoribbon stacks. Without the film protecting the STI, in some examples, the STI is significantly recessed, resulting in metal in the recessed portions between the subfins (gated subfin portions). In contrast, techniques described herein may prevent or minimize recession of the STI, and thus prevent or minimize formation of a gated subfin. Reduction or elimination of gated subfins can result in a reduction of parasitic capacitance, and thus enable device performance improvements.

IC devices/structures fabricated using techniques to reduce a gated subfin in a nanoribbon-based transistor as described herein (e.g., as described with reference to FIGS. 1-7H) may be used to implement any suitable components. For example, in various embodiments, IC devices described herein may be part of one or more of: a central processing unit, a memory device (e.g., a high-bandwidth memory device), a memory cell, a logic circuit, input/output circuitry, a field programmable gate array (FPGA) component such as an FPGA transceiver or an FPGA logic, a power delivery circuitry, an amplifier (e.g., a III-V amplifier), Peripheral Component Interconnect Express (PCIE) circuitry, Double Data Rate (DDR) transfer circuitry, a computing device (e.g., a wearable or a handheld computing device), etc.

The IC devices/structures disclosed herein, e.g., the IC structures 300, 400, 500, or any variations thereof, may be included in any suitable electronic component. FIGS. 8-11 illustrate various examples of apparatuses that may include any of the IC devices disclosed herein.

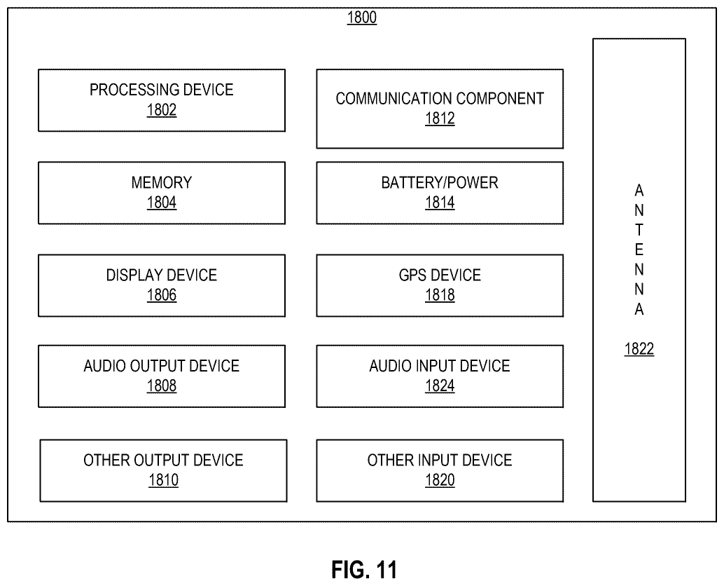

FIG. 8 is a top view of a wafer 1500 and dies 1502 that may include one or more IC structures in accordance with any of the embodiments disclosed herein. The wafer 1500 may be composed of semiconductor material and may include one or more dies 1502 having IC structures formed on a surface of the wafer 1500. Each of the dies 1502 may be a repeating unit of a semiconductor product that includes any suitable IC. After the fabrication of the semiconductor product is complete, the wafer 1500 may undergo a singulation process in which the dies 1502 are separated from one another to provide discrete “chips” of the semiconductor product. The die 1502 may include one or more IC structures as described herein (e.g., any of the IC structures 300, 400, 500, or any variations thereof described herein, or any combination of such IC structures), one or more transistors and/or supporting circuitry to route electrical signals to the transistors, as well as any other IC components. In some embodiments, the wafer 1500 or the die 1502 may include a memory device (e.g., a random-access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 1502. For example, a memory array formed by multiple memory devices may be formed on a same die 1502 as a processing device (e.g., the processing device 1802 of FIG. 11) or other logic that is configured to store information in the memory devices or execute instructions stored in the memory array.

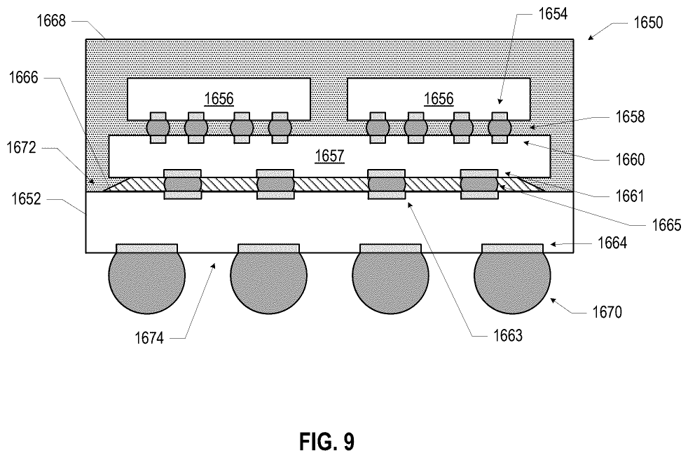

FIG. 9 is a side, cross-sectional view of an example IC package 1650 that may include one or more IC structures in accordance with any of the embodiments disclosed herein (e.g., any of the IC structures 300, 400, 500, or any variations thereof described herein, or any combination of such IC structures). In some embodiments, the IC package 1650 may be a system-in-package (SiP).

The package substrate 1652 may be formed of a dielectric material (e.g., a ceramic, a buildup film, an epoxy film having filler particles therein, glass, an organic material, an inorganic material, combinations of organic and inorganic materials, embedded portions formed of different materials, etc.), and may have conductive pathways extending through the dielectric material between the face 1672 and the face 1674, or between different locations on the face 1672, and/or between different locations on the face 1674.

The package substrate 1652 may include conductive contacts 1663 that are coupled to conductive pathways (not shown) through the package substrate 1652, allowing circuitry within the dies 1656 and/or the interposer 1657 to electrically couple to various ones of the conductive contacts 1664 (or to devices included in the package substrate 1652, not shown).

The IC package 1650 may include an interposer 1657 coupled to the package substrate 1652 via conductive contacts 1661 of the interposer 1657, first-level interconnects 1665, and the conductive contacts 1663 of the package substrate 1652. The first-level interconnects 1665 illustrated in FIG. 9 are solder bumps, but any suitable first-level interconnects 1665 may be used. In some embodiments, no interposer 1657 may be included in the IC package 1650; instead, the dies 1656 may be coupled directly to the conductive contacts 1663 at the face 1672 by first-level interconnects 1665. More generally, one or more dies 1656 may be coupled to the package substrate 1652 via any suitable structure (e.g., a silicon bridge, an organic bridge, one or more waveguides, one or more interposers, wirebonds, etc.).

The IC package 1650 may include one or more dies 1656 coupled to the interposer 1657 via conductive contacts 1654 of the dies 1656, first-level interconnects 1658, and conductive contacts 1660 of the interposer 1657. The conductive contacts 1660 may be coupled to conductive pathways (not shown) through the interposer 1657, allowing circuitry within the dies 1656 to electrically couple to various ones of the conductive contacts 1661 (or to other devices included in the interposer 1657, not shown). The first-level interconnects 1658 illustrated in FIG. 9 are solder bumps, but any suitable first-level interconnects 1658 may be used. As used herein, a “conductive contact” may refer to a portion of conductive material (e.g., metal) serving as an interface between different components; conductive contacts may be recessed in, flush with, or extending away from a surface of a component, and may take any suitable form (e.g., a conductive pad or socket).

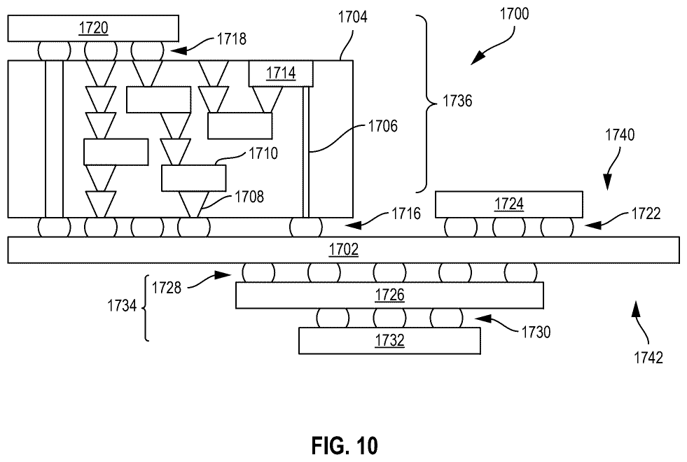

In some embodiments, an underfill material 1666 may be disposed between the package substrate 1652 and the interposer 1657 around the first-level interconnects 1665, and a mold compound 1668 may be disposed around the dies 1656 and the interposer 1657 and in contact with the package substrate 1652. In some embodiments, the underfill material 1666 may be the same as the mold compound 1668. Example materials that may be used for the underfill material 1666 and the mold compound 1668 are epoxy mold materials, as suitable. Second-level interconnects 1670 may be coupled to the conductive contacts 1664. The second-level interconnects 1670 illustrated in FIG. 9 are solder balls (e.g., for a ball grid array arrangement), but any suitable second-level interconnects 1670 may be used (e.g., pins in a pin grid array arrangement or lands in a land grid array arrangement). The second-level interconnects 1670 may be used to couple the IC package 1650 to another component, such as a circuit board (e.g., a motherboard), an interposer, or another IC package, as known in the art and as discussed below with reference to FIG. 10.

The dies 1656 may take the form of any of the embodiments of the die 1502 discussed herein. In embodiments in which the IC package 1650 includes multiple dies 1656, the IC package 1650 may be referred to as a multi-chip package (MCP). The dies 1656 may include circuitry to perform any desired functionality. For example, or more of the dies 1656 may be logic dies (e.g., silicon-based dies), and one or more of the dies 1656 may be memory dies (e.g., high-bandwidth memory).

Although the IC package 1650 illustrated in FIG. 9 is a flip chip package, other package architectures may be used. For example, the IC package 1650 may be a ball grid array (BGA) package, such as an embedded wafer-level ball grid array (eWLB) package. In another example, the IC package 1650 may be a wafer-level chip scale package (WLCSP) or a panel fanout (FO) package. Although two dies 1656 are illustrated in the IC package 1650 of FIG. 9, an IC package 1650 may include any desired number of dies 1656. An IC package 1650 may include additional passive components, such as surface-mount resistors, capacitors, and inductors disposed on the first face 1672 or the second face 1674 of the package substrate 1652, or on either face of the interposer 1657. More generally, an IC package 1650 may include any other active or passive components known in the art.

FIG. 10 is a side, cross-sectional view of an IC device assembly 1700 that may include one or more IC packages or other electronic components (e.g., a die) including one or more IC devices in accordance with any of the embodiments disclosed herein. The IC device assembly 1700 includes a number of components disposed on a circuit board 1702 (which may be, e.g., a motherboard). The IC device assembly 1700 includes components disposed on a first face 1740 of the circuit board 1702 and an opposing second face 1742 of the circuit board 1702; generally, components may be disposed on one or both faces 1740 and 1742. Any of the IC packages discussed below with reference to the IC device assembly 1700 may take the form of any of the embodiments of the IC package 1650 discussed above with reference to FIG. 9 (e.g., may include one or more of the IC structures 300, 400, 500, or any variations thereof described herein, or any combination of such IC structures).

In some embodiments, the circuit board 1702 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate.

The IC device assembly 1700 illustrated in FIG. 10 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702, and may include solder balls (as shown in FIG. 10), male and female portions of a socket, an adhesive, an underfill material, and/or any other suitable electrical and/or mechanical coupling structure.

The package-on-interposer structure 1736 may include an IC package 1720 coupled to a package interposer 1704 by coupling components 1718. The coupling components 1718 may take any suitable form for the application, such as the forms discussed above with reference to the coupling components 1716. Although a single IC package 1720 is shown in FIG. 10, multiple IC packages may be coupled to the package interposer 1704; indeed, additional interposers may be coupled to the package interposer 1704. The package interposer 1704 may provide an intervening substrate used to bridge the circuit board 1702 and the IC package 1720. The IC package 1720 may be or include, for example, a die (the die 1502 of FIG. 8), an IC device (e.g., any of the IC structures 300, 400, 500, or any variations thereof described herein, or any combination of such IC structures), or any other suitable component. Generally, the package interposer 1704 may spread a connection to a wider pitch or reroute a connection to a different connection. For example, the package interposer 1704 may couple the IC package 1720 (e.g., a die) to a set of BGA conductive contacts of the coupling components 1716 for coupling to the circuit board 1702. In the embodiment illustrated in FIG. 10, the IC package 1720 and the circuit board 1702 are attached to opposing sides of the package interposer 1704; in other embodiments, the IC package 1720 and the circuit board 1702 may be attached to a same side of the package interposer 1704. In some embodiments, three or more components may be interconnected by way of the package interposer 1704.

In some embodiments, the package interposer 1704 may be formed as a PCB, including multiple metal layers separated from one another by layers of dielectric material and interconnected by electrically conductive vias. In some embodiments, the package interposer 1704 may be formed of an epoxy resin, a fiberglass-reinforced epoxy resin, an epoxy resin with inorganic fillers, a ceramic material, or a polymer material such as polyimide. In some embodiments, the package interposer 1704 may be formed of alternate rigid or flexible materials that may include the same materials described above for use in a semiconductor substrate, such as silicon, germanium, and other group III-V and group IV materials. The package interposer 1704 may include metal lines 1710 and vias 1708, including but not limited to through-silicon vias (TSVs) 1706. The package interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as RF devices, power amplifiers, power management devices, antennas, arrays, sensors, and microelectromechanical systems (MEMS) devices may also be formed on the package interposer 1704. The package-on-interposer structure 1736 may take the form of any of the package-on-interposer structures known in the art.

The IC device assembly 1700 may include an IC package 1724 coupled to the first face 1740 of the circuit board 1702 by coupling components 1722. The coupling components 1722 may take the form of any of the embodiments discussed above with reference to the coupling components 1716, and the IC package 1724 may take the form of any of the embodiments discussed above with reference to the IC package 1720.

The IC device assembly 1700 illustrated in FIG. 10 includes a package-on-package structure 1734 coupled to the second face 1742 of the circuit board 1702 by coupling components 1728. The package-on-package structure 1734 may include an IC package 1726 and an IC package 1732 coupled together by coupling components 1730 such that the IC package 1726 is disposed between the circuit board 1702 and the IC package 1732. The coupling components 1728 and 1730 may take the form of any of the embodiments of the coupling components 1716 discussed above, and the IC packages 1726 and 1732 may take the form of any of the embodiments of the IC package 1720 discussed above. The package-on-package structure 1734 may be configured in accordance with any of the package-on-package structures known in the art.

FIG. 11 is a block diagram of an example electrical device 1800 that may include one or more IC structures 100 in accordance with any of the embodiments disclosed herein. For example, any suitable ones of the components of the electrical device 1800 may include one or more of the IC device assemblies 1700, IC packages 1650, or dies 1502 disclosed herein. A number of components are illustrated in FIG. 11 as included in the electrical device 1800, but any one or more of these components may be omitted or duplicated, as suitable for the application. In some embodiments, some or all of the components included in the electrical device 1800 may be attached to one or more motherboards. In some embodiments, some or all of these components are fabricated onto a single system-on-a-chip (SoC) die.

Additionally, in various embodiments, the electrical device 1800 may not include one or more of the components illustrated in FIG. 11, but the electrical device 1800 may include interface circuitry for coupling to the one or more components. For example, the electrical device 1800 may not include a display device 1806, but may include display device interface circuitry (e.g., a connector and driver circuitry) to which a display device 1806 may be coupled. In another set of examples, the electrical device 1800 may not include an audio input device 1824 or an audio output device 1808, but may include audio input or output device interface circuitry (e.g., connectors and supporting circuitry) to which an audio input device 1824 or audio output device 1808 may be coupled.

The electrical device 1800 may include a processing device 1802 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1802 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The electrical device 1800 may include a memory 1804, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, the memory 1804 may include memory that shares a die with the processing device 1802. This memory may be used as cache memory and may include embedded dynamic random-access memory (eDRAM) or spin transfer torque magnetic random-access memory (STT-MRAM).

In some embodiments, the electrical device 1800 may include a communication chip 1812 (e.g., one or more communication chips). For example, the communication chip 1812 may be configured for managing wireless communications for the transfer of data to and from the electrical device 1800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 1812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1812 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1812 may operate in accordance with other wireless protocols in other embodiments. The electrical device 1800 may include an antenna 1822 to facilitate wireless communications and/or to receive other wireless communications (such as AM or FM radio transmissions).

In some embodiments, the communication chip 1812 may manage wired communications, such as electrical, optical, or any other suitable communication protocols (e.g., the Ethernet). As noted above, the communication chip 1812 may include multiple communication chips. For instance, a first communication chip 1812 may be dedicated to shorter-range wireless communications such as Wi-Fi or Bluetooth, and a second communication chip 1812 may be dedicated to longer-range wireless communications such as global positioning system (GPS), EDGE, GPRS, CDMA, WiMAX, LTE, EV-DO, or others. In some embodiments, a first communication chip 1812 may be dedicated to wireless communications, and a second communication chip 1812 may be dedicated to wired communications.

The electrical device 1800 may include battery/power circuitry 1814. The battery/power circuitry 1814 may include one or more energy storage devices (e.g., batteries or capacitors) and/or circuitry for coupling components of the electrical device 1800 to an energy source separate from the electrical device 1800 (e.g., AC line power).

The electrical device 1800 may include a display device 1806 (or corresponding interface circuitry, as discussed above). The display device 1806 may include any visual indicators, such as a heads-up display, a computer monitor, a projector, a touchscreen display, a liquid crystal display (LCD), a light-emitting diode display, or a flat panel display.

The electrical device 1800 may include an audio output device 1808 (or corresponding interface circuitry, as discussed above). The audio output device 1808 may include any device that generates an audible indicator, such as speakers, headsets, or earbuds.

The electrical device 1800 may include an audio input device 1824 (or corresponding interface circuitry, as discussed above). The audio input device 1824 may include any device that generates a signal representative of a sound, such as microphones, microphone arrays, or digital instruments (e.g., instruments having a musical instrument digital interface (MIDI) output).

The electrical device 1800 may include a GPS device 1818 (or corresponding interface circuitry, as discussed above). The GPS device 1818 may be in communication with a satellite-based system and may receive a location of the electrical device 1800, as known in the art.

The electrical device 1800 may include an other output device 1810 (or corresponding interface circuitry, as discussed above). Examples of the other output device 1810 may include an audio codec, a video codec, a printer, a wired or wireless transmitter for providing information to other devices, or an additional storage device.

The electrical device 1800 may include an other input device 1820 (or corresponding interface circuitry, as discussed above). Examples of the other input device 1820 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 1800 may have any desired form factor, such as a handheld or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server device or other networked computing component, a printer, a scanner, a monitor, a set-top box, an entertainment control unit, a vehicle control unit, a digital camera, a digital video recorder, or a wearable electrical device. In some embodiments, the electrical device 1800 may be any other electronic device that processes data.

The following paragraphs provide various examples of the embodiments disclosed herein.

Example 1 provides an IC structure, including a first stack of nanoribbons and a second stack of nanoribbons over a substrate; a first region of a doped semiconductor material in the first stack of nanoribbons in a plane that is orthogonal to the substrate; a second region of a doped semiconductor material in the second stack of nanoribbons in the plane; a first subfin structure below and substantially aligned with the first stack of nanoribbons and a second subfin structure below and substantially aligned with the second stack of nanoribbons; an insulator material (e.g., STI insulator) between and coplanar with the first subfin structure and the second subfin structure; and a film including nitrogen over the insulator material in the plane.

Example 2 provides the IC structure of example 1, where: the film is absent from a region between the first subfin and the first stack of nanoribbons.

Example 3 provides the IC structure of any one of examples 1-2, where the insulator material is a first insulator material, and where: the first subfin structure and the second subfin structure include a second insulator material.

Example 4 provides the IC structure of any one of examples 1-3, where the plane is a first plane, and where: the film has a thickness in a range of 4-8 nanometers, where the thickness is a dimension of the film in a second plane substantially orthogonal to the nanoribbon.

Example 5 provides the IC structure of any one of examples 1-4, where the plane is a first plane, and where the IC structure further includes a first gate structure including a gate electrode material around first portions of first nanoribbons of the first stack; and a second gate structure including the gate electrode material around second portions of second nanoribbons of the second stack, where: the first gate structure and the second gate structure are in a second plane that is substantially orthogonal to the substrate, and the film is present over the insulator material in the second plane.

Example 6 provides the IC structure of any one of examples 1-5, where: the film is directly on the insulator material.

Example 7 provides the IC structure of any one of examples 1-6, where the film is a first film, and where the IC structure further includes a second film including nitrogen over the first stack of nanoribbons.

Example 8 provides the IC structure of example 7, further including a first gate structure including a gate electrode material around first portions of first nanoribbons of the first stack and a dielectric material between the gate electrode material and the first nanoribbons, where: the gate electrode material is around the second film, and the dielectric material is present between the gate electrode material and the second film.

Example 9 provides the IC structure of any one of examples 1-8, where: the film includes titanium and nitrogen (e.g., titanium nitride), silicon and nitrogen (e.g., silicon nitride), silicon and nitrogen and oxygen (e.g., silicon oxynitride), or titanium and nitrogen and oxygen (e.g., titanium oxynitride).

Example 10 provides the IC structure of any one of examples 1-9, further including a first gate structure including a gate electrode material around first portions of first nanoribbons of the first stack, and a dielectric material between the gate electrode material and the first nanoribbons, where: a continuous portion of the dielectric material is present between the first subfin structure and the insulator material.

Example 11 provides an IC structure, including a substrate; adjacent stacks of nanoribbons over the substrate; a region (e.g., an STI region) between the adjacent stacks of nanoribbons, where the region includes an insulator material in a first plane below the adjacent stacks of nanoribbons (e.g., below a bottom nanoribbon of the stacks), where the first plane is substantially parallel to the substrate; and a film over the insulator material in a second plane that is substantially parallel to the first plane and between the adjacent stacks of nanoribbons and the first plane, where: the film has a different material composition from the insulator material, and the film is limited, in the second plane, to the region between the adjacent stacks of nanoribbons.

Example 12 provides the IC structure of example 11, further including a first region of a doped semiconductor material in a first stack of the adjacent stacks, and a second region of a doped semiconductor material in a second stack of the adjacent stacks, where: the first region and the second region are in a third plane that is substantially orthogonal to the substrate, and the film is present over the insulator material in the third plane.

Example 13 provides the IC structure of any one of examples 11-12, where the insulator material is a first insulator material, and where the IC structure further includes adjacent subfin regions below and substantially aligned with the adjacent stacks of nanoribbons, where the film is present between the adjacent subfin regions.

Example 14 provides the IC structure of any one of examples 11-13, where: the adjacent stacks of nanoribbons include a first stack of nanoribbons; and the film is absent below the first stack of nanoribbons in a plane that is substantially orthogonal to the substrate, substantially parallel to a length of the nanoribbons of the first stack, and that intersects the nanoribbons of the first stack.

Example 15 provides the IC structure of any one of examples 11-14, where: the adjacent stacks of nanoribbons include a first stack of nanoribbons and a second stack of nanoribbons; first portions of the first stack of nanoribbons are first channel regions of a first transistor and second portions of the second stack of nanoribbons are second channel regions of a second transistor; and the film is present over the insulator material in a plane that is orthogonal to the substrate and that intersects the first portions and the second portions.

Example 16 provides the IC structure of any one of examples 11-15, where: the film is in contact with the insulator material.

Example 17 provides the IC structure of any one of examples 11-16, where the film is a first nitride-based film, and where the IC structure further includes a second nitride-based film over one or more of the adjacent stacks of nanoribbons.

Example 18 provides the IC structure of any one of examples 11-17, where: the film includes titanium and nitrogen (e.g., titanium nitride), silicon and nitrogen (e.g., silicon nitride), silicon and nitrogen and oxygen (e.g., silicon oxynitride), or titanium and nitrogen and oxygen (e.g., titanium oxynitride).

Example 19 provides an IC structure according to any one of examples 1-18, where the IC structure includes or is a part of a central processing unit.

Example 20 provides an IC structure according to any one of examples 1-19, where the IC structure includes or is a part of a memory device.

Example 21 provides an IC structure according to any one of examples 1-20, where the IC structure includes or is a part of a logic circuit.

Example 22 provides an IC structure according to any one of examples 1-21, where the IC structure includes or is a part of input/output circuitry.

Example 23 provides an IC structure according to any one of examples 1-22, where the IC structure includes or is a part of a field programmable gate array transceiver.

Example 24 provides an IC structure according to any one of examples 1-23, where the IC structure includes or is a part of a field programmable gate array logic.

Example 25 provides an IC structure according to any one of examples 1-24, where the IC structure includes or is a part of a power delivery circuitry.

Example 26 provides an IC package that includes an IC die including an IC structure according to any one of examples 1-25; and a further IC component, coupled to the IC die.

Example 27 provides an IC package according to example 26 where the further IC component includes a package substrate.

Example 28 provides an IC package according to example 26, where the further IC component includes an interposer.

Example 29 provides an IC package according to example 26, where the further IC component includes a further IC die.

Example 30 provides a computing device that includes a carrier substrate and an IC structure coupled to the carrier substrate, where the IC structure is an IC structure according to any one of examples 1-25, or the IC structure is included in the IC package according to any one of examples 26-29.

Example 31 provides a computing device according to example 30, where the computing device is a wearable or handheld computing device.

Example 32 provides a computing device according to examples 30 or 31, where the computing device further includes one or more communication chips.

Example 33 provides a computing device according to any one of examples 30-32, where the computing device further includes an antenna.

Example 34 provides a computing device according to any one of examples 30-33, where the carrier substrate is a motherboard.

Example 35 provides a method of fabricating an IC structure, the method including providing a stack of alternate layers of a semiconductor material and a further material; patterning the stack into a first fin and a second fin, where a first subfin is under the first fin and a second subfin is under the second fin; providing an insulator material (e.g., STI fill) in an opening between the first subfin and the second subfin; providing a nitride-based film over the insulator material in the opening; after providing the nitride-based film, removing the further material from the first fin and the second fin to form a first stack of nanoribbons from the first fin and a second stack of nanoribbons from the second fin; and forming transistors in the first stack of nanoribbons and in the second stack of nanoribbons.

Example 36 provides the method of example 35, where: providing the nitride-based film includes providing the nitride-based film over the first nanoribbon stack, over the second nanoribbon stack, and on sidewalls of the opening.

Example 37 provides the method of example 35, further including performing a treatment of a first portion of the nitride-based film over the insulator material but not of a second portion of the nitride-based film on the sidewalls; and removing the second portion without removing the first portion of the nitride-based film.

Example 38 provides the method of example 37, where: performing the treatment includes performing treatment of a third portion of the nitride-based film over the first nanoribbon stack and over the second nanoribbon stack.

Example 39 provides the method of any one of examples 37-38, further including removing the (untreated) second portion without removing the treated first portion of the nitride-based film.

Example 40 provides the method of any one of examples 35-39, further including providing a mask (e.g., carbon hard mask) in the opening over the nitride-based film, where the mask covers the nitride-based film over the insulator material and include openings to expose portions of the nitride-based film over the first nanoribbons stack and over the second nanoribbon stack; and removing the exposed portion of the nitride-based film.

Example 41 provides the method of example 40, where: forming the transistors includes removing the mask; providing an oxide-based film over exposed surfaces; providing a dummy gate material over the oxide-based film; forming regions of a doped semiconductor material in the first nanoribbon stack and in the second nanoribbon stack; removing the dummy gate material; and removing the oxide-based film without removing the nitride-based film over the insulator material (and without significantly etching the insulator material in the STI region).

Example 42 provides the method of any one of examples 35-41, further including after removing the further material to release nanoribbons in the first stack of nanoribbons and the second stack of nanoribbons, cleaning exposed surfaces (without significantly etching the insulator material in the STI region).

Example 43 provides the method of example 42, further including providing a gate insulator material around portions of the nanoribbons and over the insulator material (and over the nitride-based film if it is still present over the nanoribbon stacks); and depositing the gate electrode material over the gate insulator material around the nanoribbons (and around the nitride-based film if still present over the nanoribbon stacks).

Example 44 provides the method of any one of examples 35-43, further including removing at least a portion of the first subfin and of the second subfin.

Example 45 provides the method of example 44, further including prior to removing at least the portion of the first subfin and of the second subfin, flipping over the IC structure, where removing at least the portion of the first subfin and of the second subfin includes forming a first opening in the first subfin and a second opening in the second subfin; and after forming the first opening and the second opening, filling the first opening and the second opening with a second semiconductor material.

Example 46 provides a method according to any one of examples 35-45, where the IC structure is an IC structure according to any one of the preceding examples.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. An integrated circuit (IC) structure, comprising:
a first stack of nanoribbons and a second stack of nanoribbons over a substrate;
a first region of a doped semiconductor material in the first stack of nanoribbons in a plane that is orthogonal to the substrate;
a second region of a doped semiconductor material in the second stack of nanoribbons in the plane;
a first subfin structure below and substantially aligned with the first stack of nanoribbons and a second subfin structure below and substantially aligned with the second stack of nanoribbons;
an insulator material between and coplanar with the first subfin structure and the second subfin structure; and
a film comprising nitrogen over the insulator material in the plane.

2. The IC structure of claim 1, wherein:
the film is absent from a region between the first subfin and the first stack of nanoribbons.

3. The IC structure of claim 1, wherein the insulator material is a first insulator material, and wherein:
the first subfin structure and the second subfin structure include a second insulator material.

4. The IC structure of claim 1, wherein the plane is a first plane, and wherein:
the film has a thickness in a range of 4-8 nanometers, wherein the thickness is a dimension of the film in a second plane substantially orthogonal to the nanoribbon.

5. The IC structure of claim 1, wherein the plane is a first plane, and wherein the IC structure further comprises:
a first gate structure including a gate electrode material around first portions of first nanoribbons of the first stack; and
a second gate structure including the gate electrode material around second portions of second nanoribbons of the second stack, wherein:
the first gate structure and the second gate structure are in a second plane that is substantially orthogonal to the substrate, and the film is present over the insulator material in the second plane.

6. The IC structure of claim 1, wherein:
the film is directly on the insulator material.

7. The IC structure of claim 1, wherein the film is a first film, and wherein the IC structure further comprises:
a second film including nitrogen over the first stack of nanoribbons.

8. The IC structure of claim 7, further comprising:
a first gate structure including a gate electrode material around first portions of first nanoribbons of the first stack and a dielectric material between the gate electrode material and the first nanoribbons, wherein:
the gate electrode material is around the second film, and the dielectric material is present between the gate electrode material and the second film.

9. The IC structure of claim 1, wherein:
the film includes:
titanium and nitrogen, silicon and nitrogen, silicon and nitrogen and oxygen, or titanium and nitrogen and oxygen.

10. The IC structure of claim 1, further comprising:
a first gate structure including a gate electrode material around first portions of first nanoribbons of the first stack, and a dielectric material between the gate electrode material and the first nanoribbons, wherein:
a continuous portion of the dielectric material is present between the first subfin structure and the insulator material.

11. An integrated circuit (IC) structure, comprising:
a substrate;
adjacent stacks of nanoribbons over the substrate;
a region between the adjacent stacks of nanoribbons, wherein the region includes an insulator material in a first plane below the adjacent stacks of nanoribbons, wherein the first plane is substantially parallel to the substrate; and
a film over the insulator material in a second plane that is substantially parallel to the first plane and between the adjacent stacks of nanoribbons and the first plane, wherein:
the film has a different material composition from the insulator material, and the film is limited, in the second plane, to the region between the adjacent stacks of nanoribbons.

12. The IC structure of claim 11, further comprising:
a first region of a doped semiconductor material in a first stack of the adjacent stacks, and a second region of a doped semiconductor material in a second stack of the adjacent stacks, wherein:
the first region and the second region are in a third plane that is substantially orthogonal to the substrate, and the film is present over the insulator material in the third plane.

13. The IC structure of claim 11, wherein the insulator material is a first insulator material, and wherein the IC structure further comprises:
adjacent subfin regions below and substantially aligned with the adjacent stacks of nanoribbons, wherein the film is present between the adjacent subfin regions.

14. The IC structure of claim 11, wherein:
the adjacent stacks of nanoribbons include a first stack of nanoribbons; and
the film is absent below the first stack of nanoribbons in a plane that is substantially orthogonal to the substrate, substantially parallel to a length of the nanoribbons of the first stack, and that intersects the nanoribbons of the first stack.

15. The IC structure of claim 11, wherein:
the adjacent stacks of nanoribbons include a first stack of nanoribbons and a second stack of nanoribbons;
first portions of the first stack of nanoribbons are first channel regions of a first transistor and second portions of the second stack of nanoribbons are second channel regions of a second transistor; and
the film is present over the insulator material in a plane that is orthogonal to the substrate and that intersects the first portions and the second portions.

16. The IC structure of claim 11, wherein:
the film is in contact with the insulator material.

17. The IC structure of claim 11, wherein the film is a first nitride-based film, and wherein the IC structure further comprises:
a second nitride-based film over one or more of the adjacent stacks of nanoribbons.

18. A method of fabricating an integrated circuit (IC) structure, the method comprising:
providing a stack of alternate layers of a semiconductor material and a further material;
patterning the stack into a first fin and a second fin, wherein a first subfin is under the first fin and a second subfin is under the second fin;
providing an insulator material in an opening between the first subfin and the second subfin;
providing a film comprising nitrogen over the insulator material in the opening;
after providing the film, removing the further material from the first fin and the second fin to form a first stack of nanoribbons from the first fin and a second stack of nanoribbons from the second fin; and
forming transistors in the first stack of nanoribbons and in the second stack of nanoribbons.

19. The method of claim 18, wherein:
providing the film includes providing the film over the first nanoribbon stack, over the second nanoribbon stack, and on sidewalls of the opening.

20. The method of claim 19, further comprising:
performing a treatment to a first portion of the film over the insulator material but not to a second portion of the film on the sidewalls; and
removing the second portion without removing the first portion of the film.
